(19) United States
(12) Patent Application Publication
(10) Pub. No.: US 2025/0081529 A1
(43) Pub. Date: Mar. 6, 2025

(54) SEMICONDUCTOR DEVICES WITH EPITAXIAL SOURCE/DRAIN REGION WITH A BOTTOM DIELECTRIC AND METHODS OF FABRICATION THEREOF

(71) Applicant: TAIWAN SEMICONDUCTOR MANUFACTURING COMPANY, LTD., Hsinchu (TW)

(72) Inventors: Chien-Chia CHENG, Hsinchu (TW); Chih-Chiang CHANG, Hsinchu (TW); Ming-Hua YU, Hsinchu (TW); Chii-Horng LI, Hsinchu (TW); Chung-Ting KO, Kaohsiung (TW); Sung-En LIN, Hsinchu (TW); Chih-Shan CHEN, New Taipei (TW); De-Fang CHEN, Hsinchu (TW)

(21) Appl. No.: 18/593,444

(22) Filed: Mar. 1, 2024

Related U.S. Application Data
(63) Continuation-in-part of application No. 18/405,146, filed on Jan. 5, 2024.
(60) Provisional application No. 63/610,117, filed on Dec. 14, 2023.
(60) Provisional application No. 63/536,604, filed on Sep. 5, 2023.

(51) Int. Cl. H01L 29/423; H01L 21/8234; H01L 27/088; H01L 29/06; H01L 29/08; H01L 29/66; H01L 29/775; H01L 29/78; H01L 29/786

(52) U.S. Cl. CPC H10D 30/6735; H10D 30/014; H10D 30/43; H10D 30/6757; H10D 30/797; H10D 62/121; H10D 62/151; H10D 64/017; H10D 64/018; H10D 84/013; H10D 84/038; H10D 84/83

(57) ABSTRACT

Embodiments with present disclosure provides a gate-all-around FET device including extended bottom inner spacers. The extended bottom inner prevents the subsequently formed epitaxial source/drain region from volume loss and induces compressive strain in the channel region to prevent strain loss and channel resistance degradation.

### CROSS-REFERENCE TO RELATED APPLICATIONS

This application is a continuation-in-part of U.S. patent application Ser. No. 18/405,146 filed on Jan. 5, 2024, which claims priority to United States Provisional patent application Ser. No. 63/536,604, filed Sep. 5, 2023 and Ser. No. 63/610,117 filed on Dec. 14, 2023. Each of the aforementioned applications is incorporated by reference in its entirety.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area. As minimum feature size reduces, side effects, such as leakage, parasitic devices, resistance degradation, etc., may occur. Therefore, there is a need to solve the above problems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1K schematically demonstrate a semiconductor device according to embodiments of the present disclosure.

FIG. 2 is a flow chart of a method for manufacturing of a semiconductor substrate according to embodiments of the present disclosure.

FIGS. 3A-3R schematically illustrate various stages of manufacturing a semiconductor device according to embodiments of the present disclosure.

FIGS. 4A-4L schematically demonstrate structural details of semiconductor devices according to embodiments of the present disclosure.

FIGS. 5A-5L schematically demonstrate structural details of semiconductor devices according to embodiments of the present disclosure.

FIGS. 6A-6F schematically demonstrate a semiconductor device according to embodiments of the present disclosure.

FIG. 7 is a flow chart of a method for manufacturing of a semiconductor substrate according to embodiments of the present disclosure.

FIGS. 8A-8D schematically illustrate various stages of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

Embodiments of the present disclosure relate to a semiconductor device including a nanosheet channel region with reduced channel resistance (R_{ch}). Particularly, embodiments of the present disclosure provide a GAA semiconductor device with reduced channel resistance for source/drain epitaxial region in P-type FET. Particularly, embodiments of the present disclosure provide a GAA device formed from a semiconductor stack including a bottom dielectric film at a bottom surface of a source/drain region to prevent leakage currents through parasitic devices. In some embodiments, the bottom dielectric film may be patterned or otherwise shaped to allow the source/drain region to grow below a lower most layer of the semiconductor stack. Embodiments of the present disclosure provide improvement to AC performance and avoids serious DC performance loss from R_{ch} degradation. For example, by patterning or shaping the bottom dielectric layer, the subsequently formed epitaxial source/drain region does not surfer volume loss and may induce compressive strain in the channel region to prevent strain loss and R_{ch} degradation.

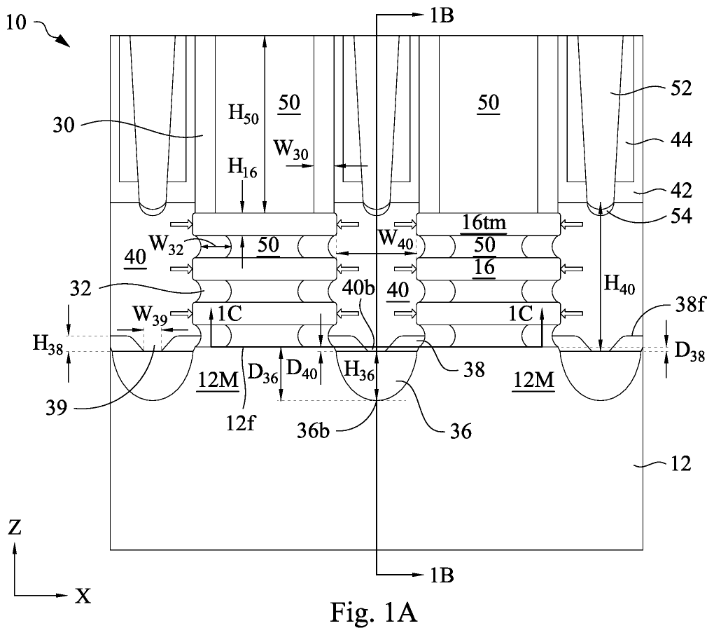

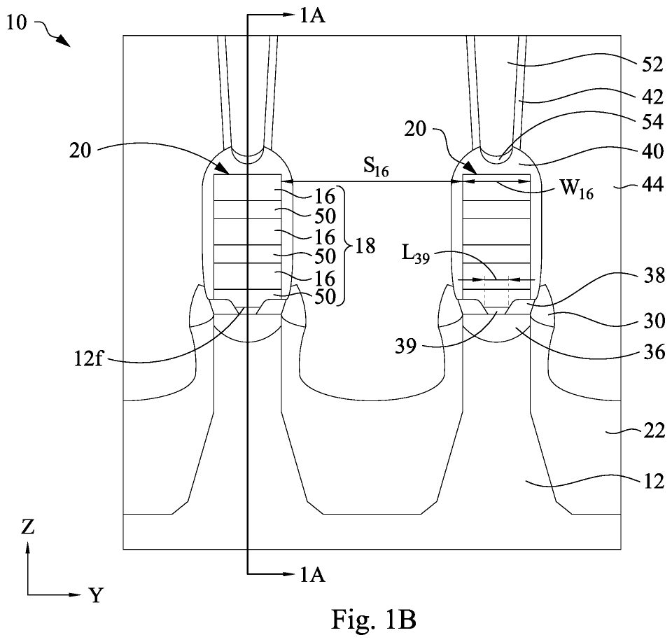

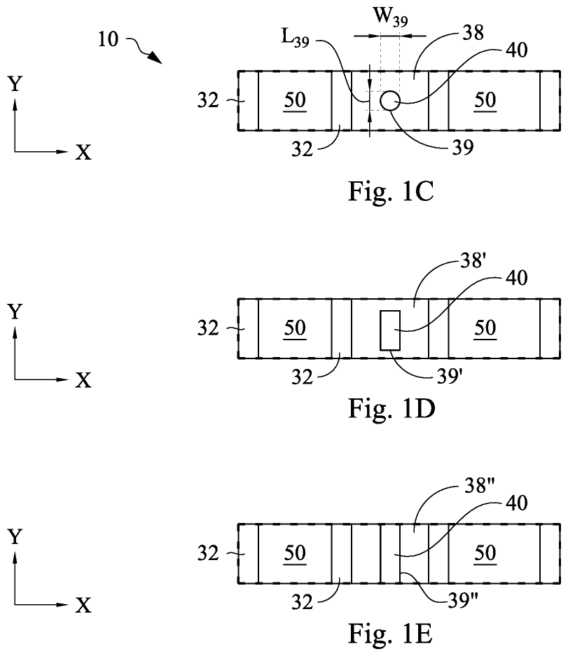

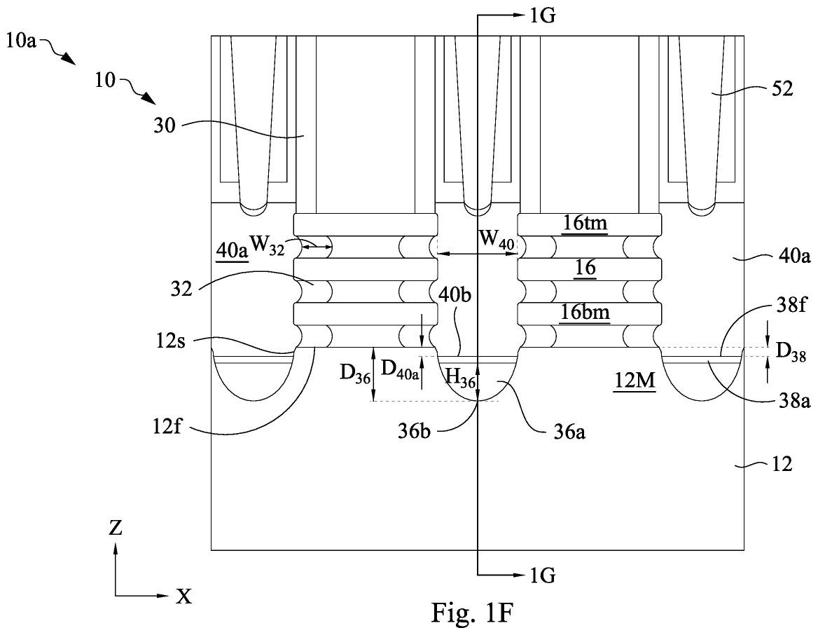

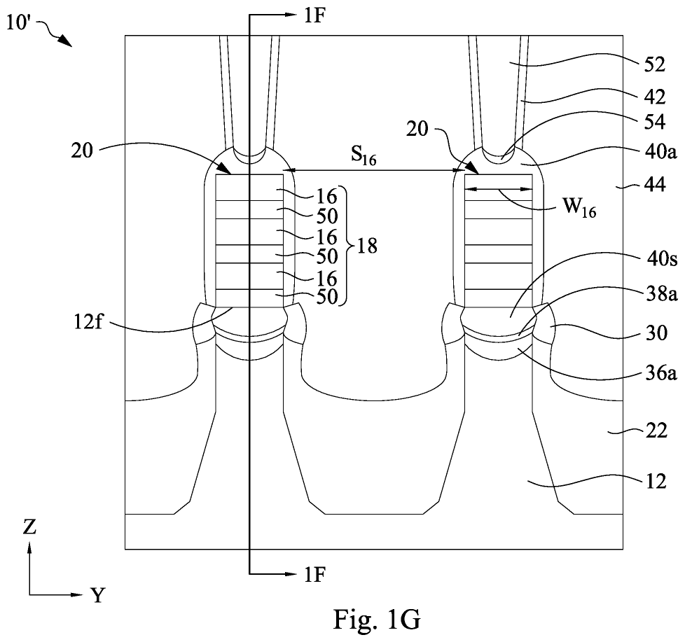

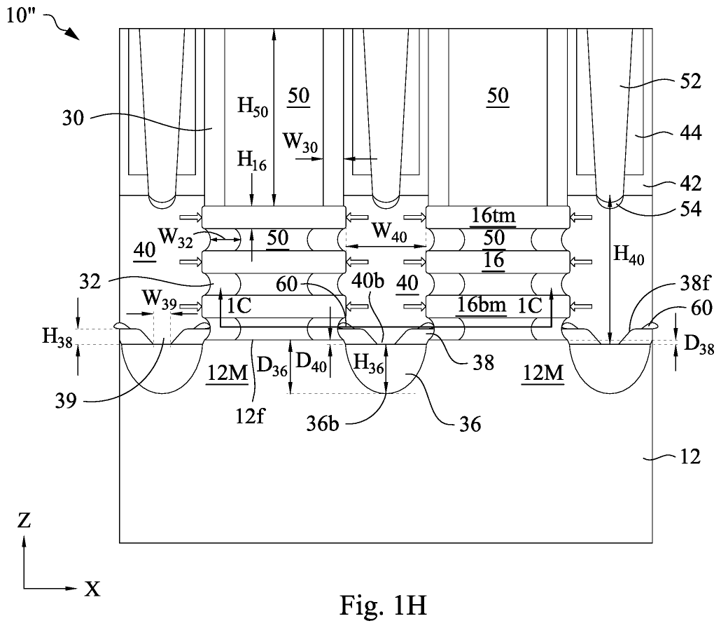

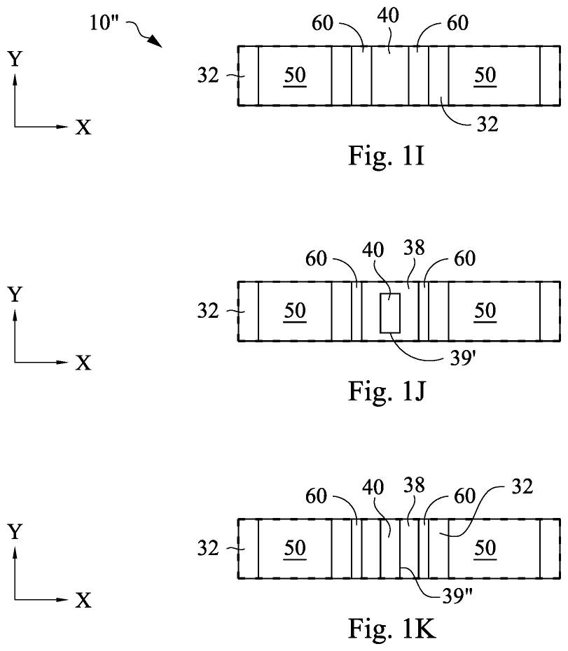

FIGS. 1A-1E schematically demonstrate a semiconductor device 10 according to embodiments of the present disclosure. FIGS. 1A-1C are cross-sectional views of the semiconductor device 10 according to the present disclosure. FIG. 1A is a cross-sectional view of the semiconductor device 10 along the line 1A-1A in FIG. 1B. FIG. 1B is a cross-sectional view of the semiconductor device 10 along the line 1B-1B in FIG. 1A. FIG. 1C is a partial cross-sectional view of the semiconductor device 10 along the line 1C-1C in FIG. 1A.

The semiconductor device 10 is a GAA device including semiconductor channels 16 formed between epitaxial source/drain regions 40. Gate structures 50 are formed over and surrounding the semiconductor channels 16. The semiconductor device 10 is formed by patterning a semiconductor stack 18 on a substrate 12 into semiconductor fins 20, forming sacrificial gate structures over the semiconductor fins 20, recessing the semiconductor fins 20 outside the sacrificial gate structures to form the epitaxial source/drain regions 40, and replacing the sacrificial gate structures with the gate structures 50.

In some embodiments, the semiconductor device 10 includes a bottom dielectric layer 38 disposed between the epitaxial source/drain regions 40 and a bottom epitaxial layer 36. The bottom dielectric layer 38 provides isolation between the epitaxial source/drain region 40 and a mesa region 12M of the semiconductor substrate 12. The bottom epitaxial layer 36 may be an epitaxial semiconductor layer formed in the recess in the semiconductor substrate 12 between the mesa region 12M. The bottom epitaxial layer 36 is formed in the space of the semiconductor fins 20. As shown in FIG. 1B, the bottom epitaxial layer 36 is in contact with a shallow trench isolation layer 22 and/or the sidewall spacers 3O. In some embodiments, the bottom epitaxial layer 36 is an epitaxial semiconductor material formed from the semiconductor substrate 12. The bottom epitaxial layer 36 may be a transitional layer between the crystalline structures of the semiconductor substrate 12 and the epitaxial source/drain region 40. In some embodiments, the bottom epitaxial layer 36 may be used as an alignment feature for forming backside source/drain contacts.

The bottom dielectric layer 38 is formed on the bottom epitaxial layer 36 and partially covers the bottom epitaxial layer 36. In some embodiments, an opening 39 is formed through the bottom dielectric layer 38 exposing a portion of the bottom epitaxial layer 36. As a result, the bottom epitaxial layer 36, along with the semiconductor channel layers 16, function as a seed layer in growing the epitaxial source/drain regions 40. As shown in FIG. 1A, the semiconductor stack 18 is formed on a top surface 12f of the semiconductor substrate 12. The top surface 12f may also be referred to as a sheet bottom. Because the epitaxial source/drain regions 40 is formed from a portion of the bottom epitaxial layer 36, the epitaxial source/drain regions 40 extend below the top surface 12f or the sheet bottom. In some embodiments, the bottom epitaxial layer 36 may be omitted and the bottom dielectric layer 38 is directly formed in the recess on the semiconductor substrate 12.

The epitaxial source/drain region 40 are formed in physical contact with the semiconductor channel layers 16. Using a portion of the bottom semiconductor layer 36 as seed layer to grow the epitaxial source/drain region 40 increases the volume of the source/drain region 40. The increased volume of the epitaxial source/drain region 40 adds compressive force F to the semiconductor channel layers 16. The increased compressive force F causing compressive strain in the semiconductor channel layers 16 thereby increasing mobility of the channel region. The semiconductor channels 16 are separated by inner spacers 32 and are surrounded by the replacement gate 50. The replacement gate 50 may be a gate stack including an interfacial layer, a gate dielectric layer, and agate electrode layer. The gate electrode layer may further include one or more work function layers and one or more metal fill layers. Sidewall spacers 30 are disposed between the epitaxial source/drain regions 40 and the gate structure 50.

The semiconductor device 10 may further include source/drain contacts 52 disposed on the epitaxial source/drain regions 40. A silicide layer 54 may be formed between the source/drain contacts 52 and the epitaxial source/drain regions 40 to facilitate electrical connection therebetween. A contact etch stop layer (CESL) 42 is deposited over the epitaxial source/drain regions 40 to protect the epitaxial source/drain regions 40 during formation. An interlayer dielectric (ILD) 44 is deposited over the CESL 42 to provide electrical isolation to the S/D contacts 52 and the epitaxial source/drain regions 40.

During operation, when a gate bias greater than a threshold voltage is applied on the gate structure 50, a conductive channel is formed within the semiconductor channel layers 16. If appropriate bias is applied to the epitaxial source/drain regions 40 via the source/drain contacts 52, current flows between the epitaxial source/drain regions 40 through the channels formed within the semiconductor channel layers 16. During the above operating condition, a portion of the gate structure 50 closest to the mesa region 12M can form a parasitic FET. If the epitaxial source/drain regions 40 were in physical contact with the mesa region 12M, an unwanted leakage current could flow between the epitaxial source/drain region 40 via the mesa portion 12M. The bottom dielectric layer 38 in the semiconductor device 10 offers adequate electrical isolation to the epitaxial source/drain regions 40 and leakage current suppression.

In some embodiments, the semiconductor device 10 is formed on a bulk semiconductor substrate 12, e.g., as opposed to an SOI substrate. In some embodiments, the semiconductor substrate 12 includes crystalline silicon (Si) or another elementary semiconductor, such as germanium (Ge). Alternatively the semiconductor substrate 12 may include (i) a compound semiconductor like silicon carbide (SiC), gallium arsenide (GaAs), gallium phosphide (GaP), indium phosphide (InP), indium arsenide (InAs), and/or indium antimonide (InSb); (ii) an alloy semiconductor like silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and/or gallium indium arsenide phosphide (GaInAsP); or (iv) combinations thereof.

The semiconductor stack 18 may include the semiconductor channel layers 16 alternatively arranged with sacrificial semiconductor layers (not shown). In some embodiments, the number of semiconductor channel layers 16 is between 1 and 6. The semiconductor channel layers 16 may be formed by a molecular beam epitaxy (MBE) process, a metalorganic chemical vapor deposition (MOCVD) process, and/or other suitable epitaxial growth processes. In some embodiments, the semiconductor channel layers 16 may include the same material as the substrate 10. In some embodiments, the semiconductor channel layers 16 may include different materials than the substrate 10. In some embodiments, the semiconductor channel layers 16 and the sacrificial semiconductor layers are made of materials having different lattice constants. In some embodiments, the sacrificial semiconductor layers include epitaxially grown silicon germanium (SiGe) layers and the semiconductor channel layers 16 include epitaxially grown silicon (Si) layers. Alternatively, in some embodiments, either of the semiconductor channel layers 16 and the sacrificial layers may include other materials such as Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof.

In some embodiments, each of the semiconductor channel layer 16 has a channel height H16 along the z-direction in a range between about 5 nm and about 15 nm. In some embodiments, the semiconductor channel layers 16 in the semiconductor stack 18 are uniform in channel height H16. In some embodiments, the semiconductor channel layers 16 in the semiconductor stack 18 have variation in the channel height H16. In some embodiments, the semiconductor channel layers 16 have a channel width W16 along the y-direction in a range between about 6 nm and about 80 nm. In some embodiments, the fins 20 or the epitaxial source/drain regions 40 have a spacing S₄₀ along the y-direction in a range between about 6 nm and about 115 nm.

In some embodiments, for a p-type device, the epitaxial source/drain regions 40 may include boron-doped (B-doped) silicon-germanium (SiGe), B-doped germanium (Ge), B-doped germanium-tin (GeSn), or combinations thereof. In some embodiments, for an n-type device, the epitaxial source/drain regions 40 may include arsenic (As) or phosphorous (P)-doped silicon (Si), carbon-doped silicon (Si:C), or combinations thereof. In some embodiments, the epitaxial source/drain regions 40 can include two or more epitaxially-grown layers, which will be discussed later, but not shown in FIGS. 1A-1C for simplicity. In some embodiments, the epitaxial source/drain regions 40 are grown from exposed sidewall surfaces of the semiconductor channel layers 16 and the exposed portion of the bottom epitaxial layer 36.

In some embodiments, the epitaxial source/drain regions 40 have a width W40 along the x-direction in a range between about 9 nm and about 32 nm. In some embodiments, the epitaxial source/drain regions 40 have a height H₄₀ along the z-direction in a range between about 20 nm and about 105 nm. The height H₄₀ is increased because bottom portions of the epitaxial source/drain regions 40 grow from the bottom epitaxial layer 36 which is below the top surface 12f of the mesa portion 12M or the bottom of the semiconductor stack 18. In some embodiments, a drop distance D₄₀ of the epitaxial source/drain regions 40, which is defined by the distance between the top surface 12f of the mesa portion 12M and a bottom surface 40b of the epitaxial source/drain regions 40, is in a range between 0 nm and about 80 nm.

In some embodiments, the bottom epitaxial layer 36 is undoped semiconductor layer. For example, the bottom epitaxial layer 36 may include SiₓGe₁₋ₓ, wherein x is in a range between 0.1 and 1. In some embodiments, the bottom epitaxial layer 36 has a height H₃₆ along the z-direction in a range between about 0 nm and about 50 nm. In some embodiments, a depth of D₃₆ of the bottom epitaxial layer 36, which is defined by the distance between the top surface 12f of the mesa portion 12M and a bottom surface 36b of the bottom epitaxial layer 36 along the z-direction, is in a range between about 3 nm and about 50 nm.

In some embodiments, the bottom dielectric layer 38 may include any suitable dielectric material, for example, oxides, such as silicon oxide, germanium oxide, nitrides, such as silicon nitride, a carbide, or other suitable dielectric materials. In some embodiments, the bottom dielectric layer 38 may include one or more dielectric material with a resistivity higher than about 1×10¹⁰ Ohms·m. In some embodiments, the bottom dielectric layer 38 has a thickness H₃₈ in the z-direction in a range between 0 nm and about 30 nm, for example, the bottom dielectric layer 38 may have a thickness H₃₈ between about 10 nm and about 20 nm.

The bottom dielectric layer 38 may be formed at a level near the top surface 12f of the mesa portion 12M. Depending on the design, a top surface 38f of the bottom dielectric layer 38 may be formed below or above the top surface 12f of the mesa portion 12M. In some embodiments, a drop distance D₃₈ of the bottom dielectric layer 38, which is defined by the distance between the top surface 12f of the mesa portion 12M and a lowest point of the bottom dielectric layer 38, is in a range between −15 nm and about 15 nm. A positive drop distance D₃₈ indicates that the entire bottom dielectric layer 38 is above the top surface 12f of the mesa portion 12M. A negative drop distance D₃₈ indicates that the bottom surface 38b of the bottom dielectric layer 38 is below the top surface 12f of the mesa portion 12M, as shown in FIGS. 1A-1B.

In the embodiment of FIGS. 1A and 1B, the bottom dielectric layer 38 has a negative drop distance D₃₈. As a result, the mesa portion 12M is not exposed to the epitaxial source/drain regions 40. The epitaxial source/drain regions 40 in the semiconductor device 10 are partially electrically decoupled from the bottom epitaxial layer 36 and the mesa region 12M.

The opening 39 is formed through the bottom dielectric layer 38 to expose a portion of the bottom epitaxial layer 36 for the epitaxial source/drain region 40 to grow from a region below the top surface 12f of the mesa portion 12M. In some embodiments, the opening 39 is formed by patterning. Location and dimension of the opening 39 may be determined according to circuit design. For example, the dimension and location of the opening 39 may be designed to achieve desirable shape and volume for the initial growth of the epitaxial source/drain regions 40.

FIG. 1C schematically illustrates the shape and location of the opening 39 according to one embodiment of the present disclosure. In FIG. 1C, the opening 39 is formed near the center region of the bottom dielectric layer 38. In some embodiments, the opening 39 may a width W39 in the x-direction in a range between 0 nm and about 30 nm, and a length L39 in the y-direction in a range between 0 nm and about 30 nm. In some embodiments, the opening 39 may be substantially circular. In other embodiments, the opening 39 may have a squared shape and symmetrical along the x and y directions.

Alternatively, the opening 39 may have other shapes, such as rectangular, or non-symmetrical. FIGS. 1D and 1E schematically illustrate two alternative embodiments. In FIG. 1D, a rectangular opening 39′ is formed through a bottom dielectric layer 38′. In FIG. 1D, the bottom dielectric layer 38′ is still a continuous film. In FIG. 1E, a slot 39″ is formed through a bottom dielectric layer 38″. The slot 39″ divides the bottom dielectric layer 38″ into two separate portions. In FIG. 1D, the bottom dielectric layer 38″ is not a continuous film.

As discussed above, the space between and above the semiconductor channel layers 16 are occupied by the gate structure 50. The gate structure 50 may extend above the top most semiconductor channel layer 16tm for a height H₅₀. The gate structure 50 may include an interfacial layer, a gate dielectric layer and gate electrode layer.

In some embodiments, the gate structure 50 occupies a middle portion of the semiconductor channel layers 16. Edge portions of the semiconductor channel layers 16 are covered by the inner spacers 32. The gate side wall spacers 30 are disposed on both sides of the gate structures 50 except between the semiconductor channel layers 16. In some embodiments, the height H₅₀ of the gate structure 50 along the y-direction ranges between about 5 nm and about 50 nm. In some embodiments, the sidewall spacers 30 and the inner spacers 32 may include a nitride, such as silicon nitride (Si₃N₄ or “SiN”), silicon carbon nitride (SiCN), and silicon carbon oxy-nitride (SiCON). In some embodiments, a width W₃₀ of the sidewall spacers 30 along the x-direction ranges between about 3 nm and about 8 nm. In some embodiments, a width W32 of the inner spacers 32 along the x-direction ranges between about 5 nm and about 10 nm. The inner spacers 32 are interposed between the gate structure 50 and the epitaxial source/drain regions 40 to electrically isolate the gate structure 50 from epitaxial source/drain regions 40.

The silicide layers 54, which are interposed between the source/drain contacts 52 and epitaxial source/drain region 40, can include titanium silicide (TiSi), nickel silicide (NiSi), cobalt silicide (CoSi), platinum-silicide (PtSi), or a suitable silicide material. By way of example and not limitation, each silicide layer 54 may have a thickness between about 4 nm and about 8 nm. In some embodiments, the silicide layer reduces the contact resistance between the source/drain contact 53 and the epitaxial source/drain region 40.

In some embodiments, the ILD layer 44 includes one or more layers of dielectric material. In some embodiments, the ILD layer 44 is a silicon oxide based dielectric with nitrogen, hydrogen, carbon, or combinations thereof. According to some embodiments, the ILD layer 44 provides electrical isolation and structural support to the gate structure 50, the source/drain contacts 52, and the epitaxial source/drain regions 40.

FIGS. 1F-1G schematically demonstrate a semiconductor device 10′ according to embodiments of the present disclosure. FIGS. 1F-1G are cross-sectional views of the semiconductor device 10′ according to the present disclosure. FIG. 1F is a cross-sectional view of the semiconductor device 10′ along the line 1F-1F in FIG. 1G. FIG. 1G is a cross-sectional view of the semiconductor device 10 along the line 1G-1G in FIG. 1F.

The semiconductor device 10′ is similar to the semiconductor device 10 except that the semiconductor device 10′ includes a bottom dielectric layer 38a formed below the top surface 12f of the mesa portion 12M. In some embodiments, the bottom dielectric layer 38a is a continuous film deposited on a bottom epitaxial layer 36a. In some embodiments, the bottom dielectric layer 38a covers a top surface of the bottom epitaxial layer 36a. A mesa sidewall 12s of the mesa portion 12M is not covered by the bottom dielectric layer 36a. That is to say that the bottom dielectric layer 38a partially cover the semiconductor surface in the recess 34 below the top surface 12f, which includes the top surface 36t of the bottom epitaxial layer 36 and the sidewalls 12s of the mesa region 12M. As a result, the mesa sidewall 12s also functions as a seed layer during formation of an epitaxial source/drain region 40a. In some embodiments, a drop distance D₄₀a of the epitaxial source/drain regions 40a, which is defined by the distance between the top surface 12f of the mesa portion 12M and a bottom surface 40b of the epitaxial source/drain regions 40a, is in a range between 0 nm and about 50 nm. The bottom dielectric layer 38a has a negative drop distance D₃₈. As a result, the mesa portion 12M is exposed to the epitaxial source/drain regions 40. The epitaxial source/drain regions 40a in the semiconductor device 10a are partially electrically decoupled from the bottom epitaxial layer 36a and the mesa region 12M.

FIGS. 1H-1K schematically demonstrate a semiconductor device 10″ according to embodiments of the present disclosure. FIG. 1H is a cross-sectional view of the semiconductor device 10″. FIG. 1I is a partial cross-sectional view of the semiconductor device 10″ along the line 1I-11 in FIG. 1H.

The semiconductor device 10″ is similar to the semiconductor device 10 except that the semiconductor device 10″ includes an air gap 60 disposed between the bottom dielectric layer 38 and the epitaxial source/drain region 40. In some embodiments, the air gap 60 may be open to the inner spacers 32. The air gaps 60 may be result of merger of an epitaxial section grown from the semiconductor channel layer 16 and an epitaxial section grown from the bottom epitaxial layer 36. In some embodiments, the air gaps 60 may be designed to increase isolation around the epitaxial source/drain region 40. As shown in FIG. 1I, the air gaps 60 may extend along the y-direction.

FIGS. 1J and 1K schematically illustrate two alternative embodiments with rectangular openings and slot openings. In FIG. 1J, the air gaps 60 are formed near the rectangular opening 39′ through the bottom dielectric layer 38′. In FIG. 1K, the air gaps 60 are formed near the slot 39″ formed through the bottom dielectric layer 38″.

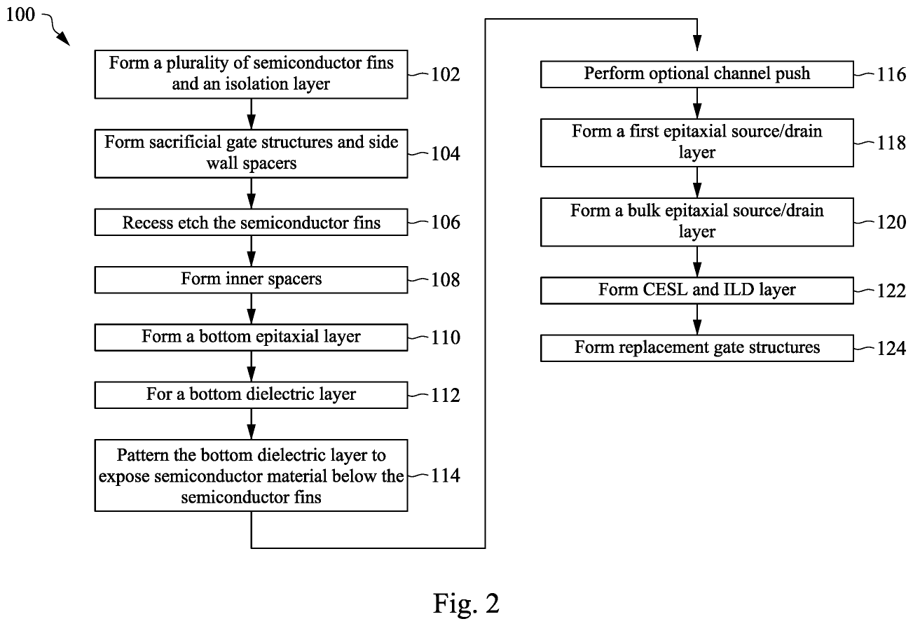

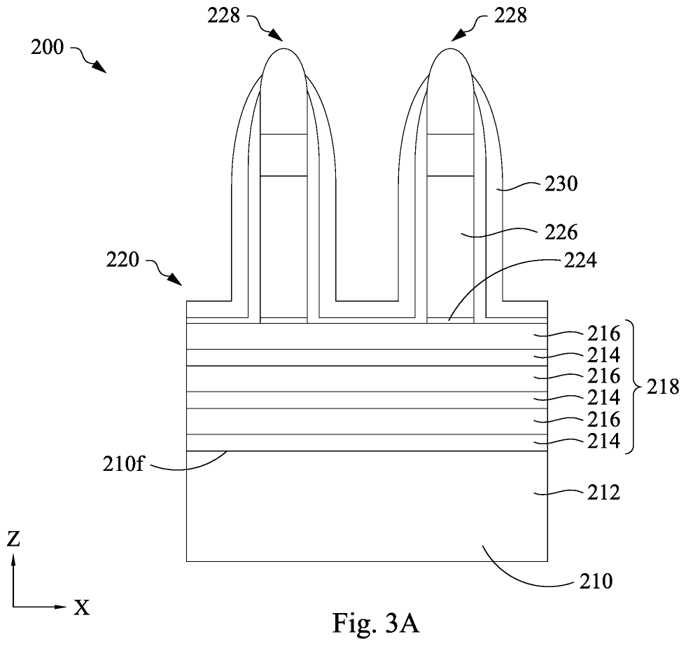

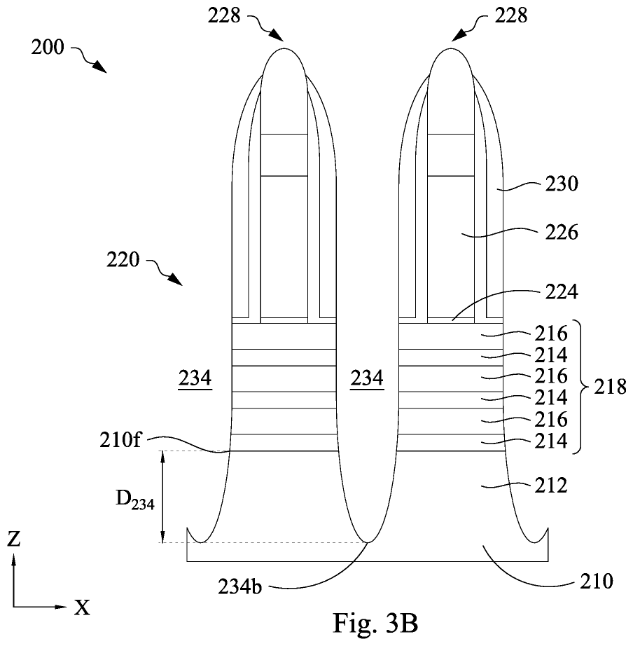

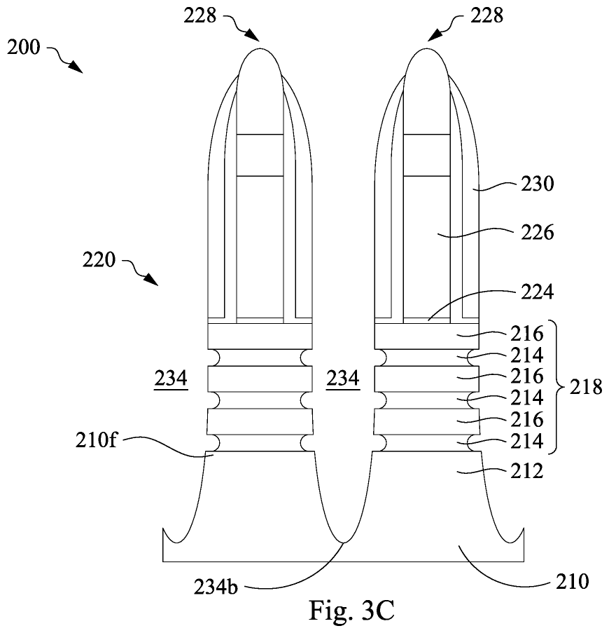

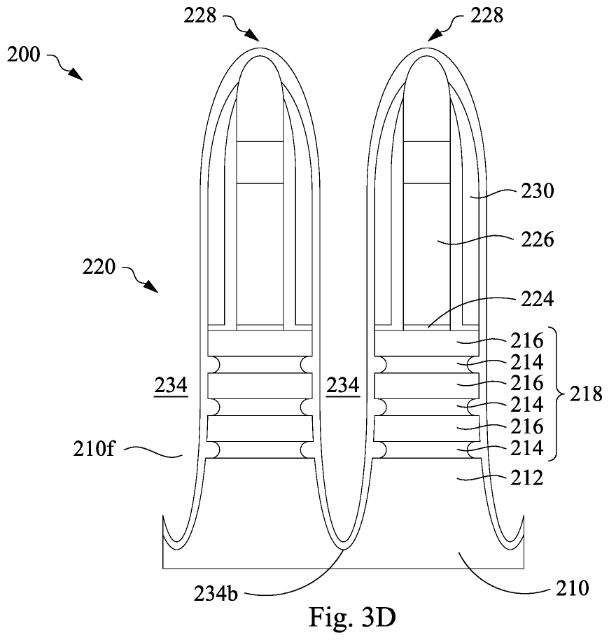

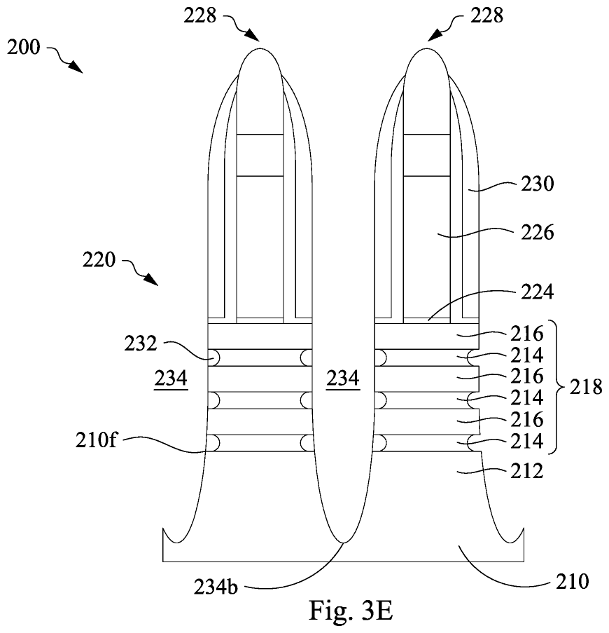

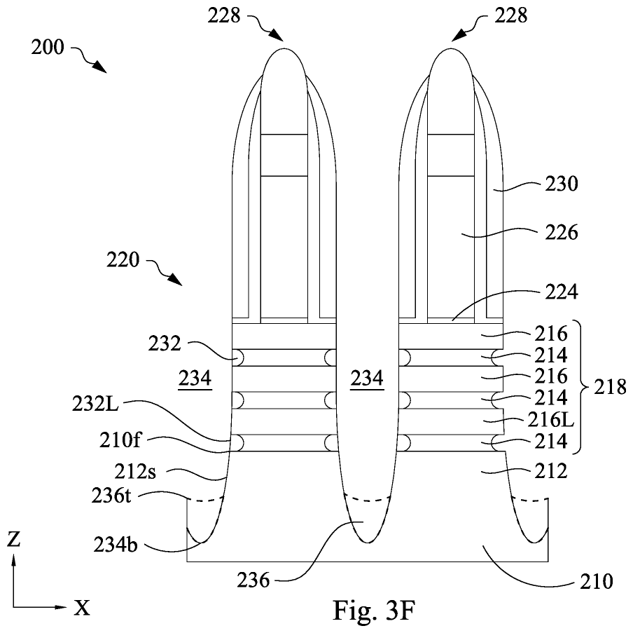

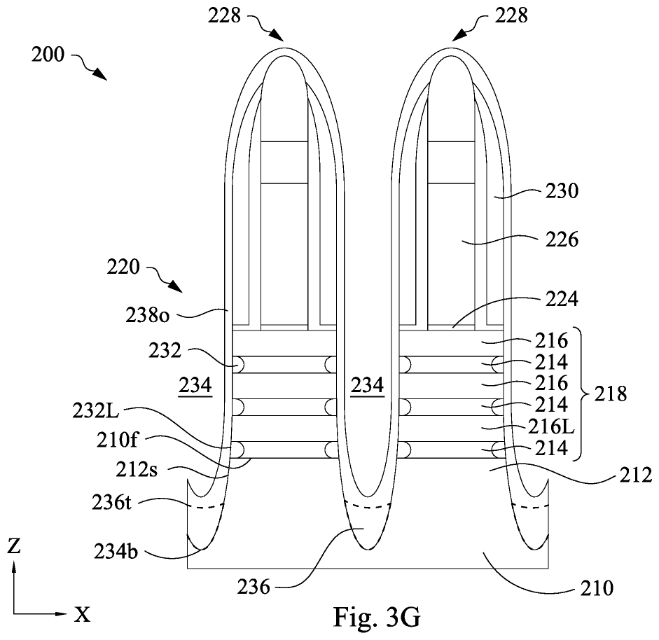

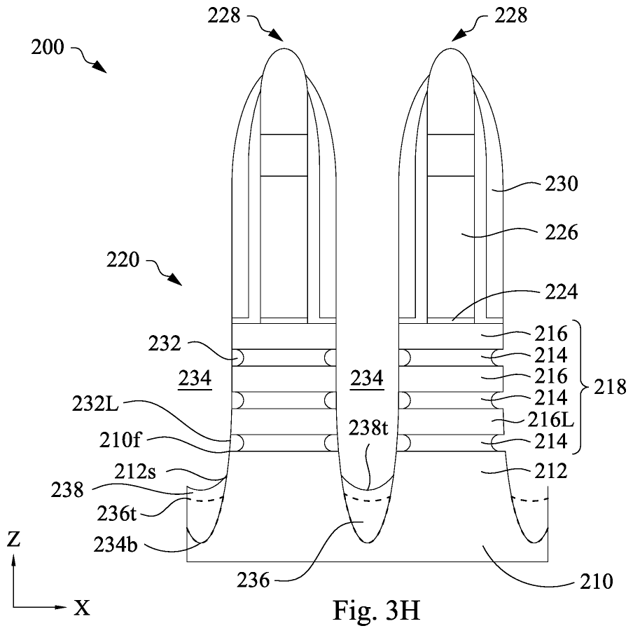

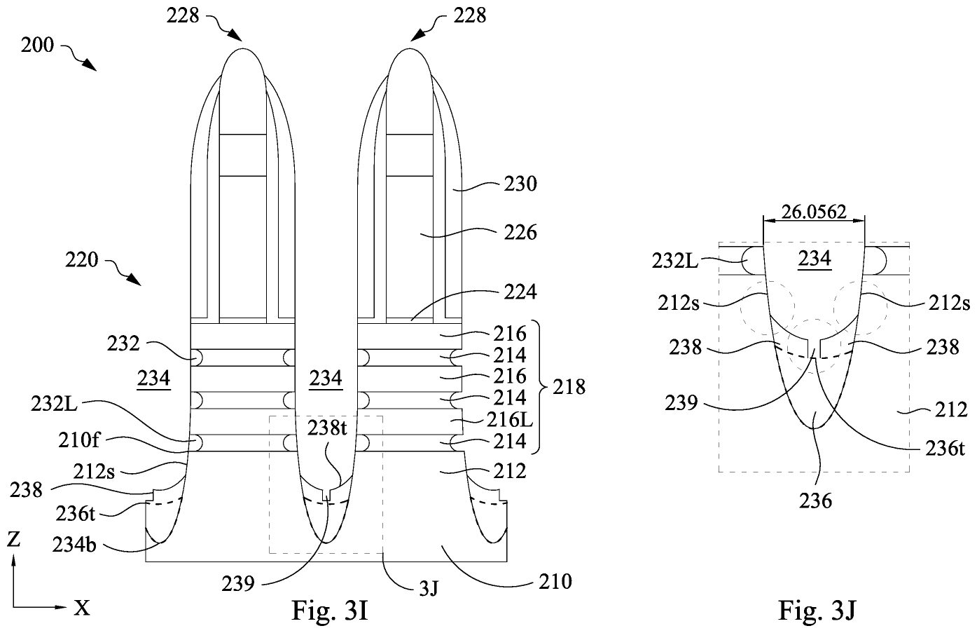

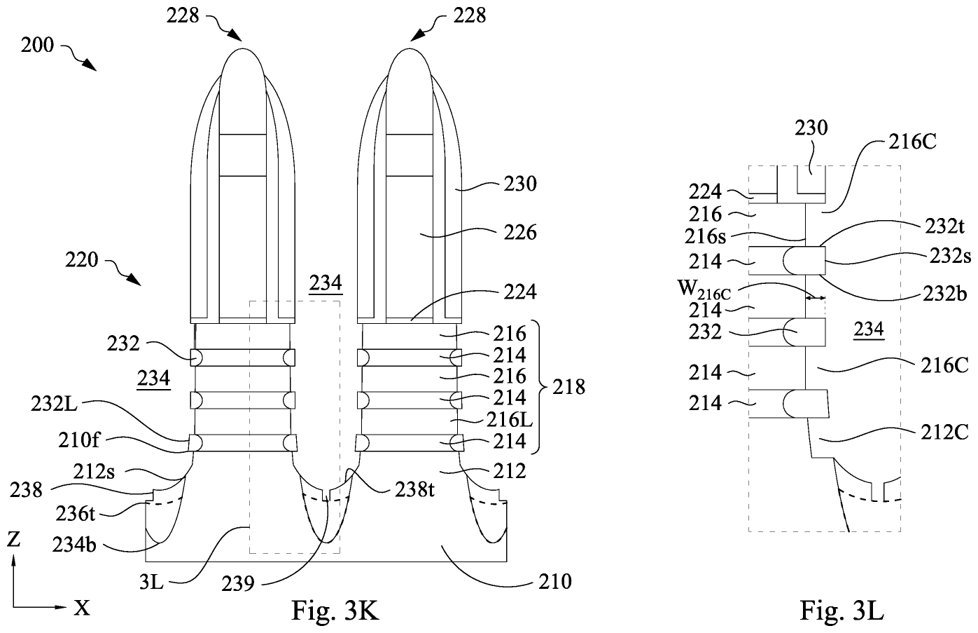

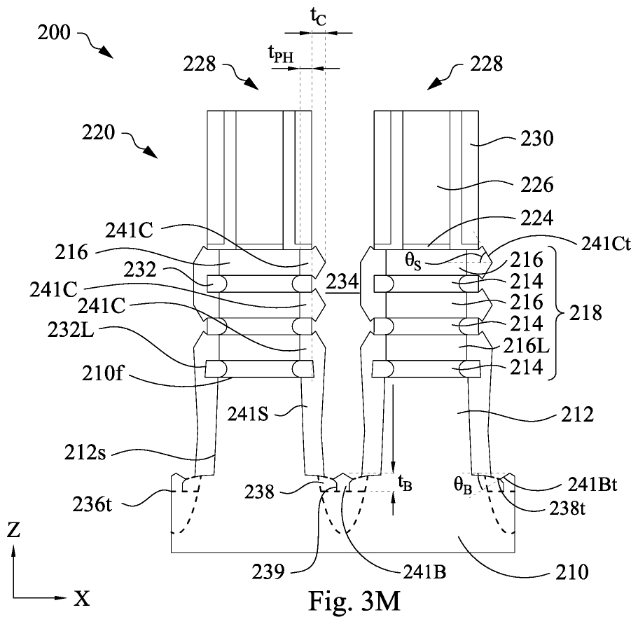

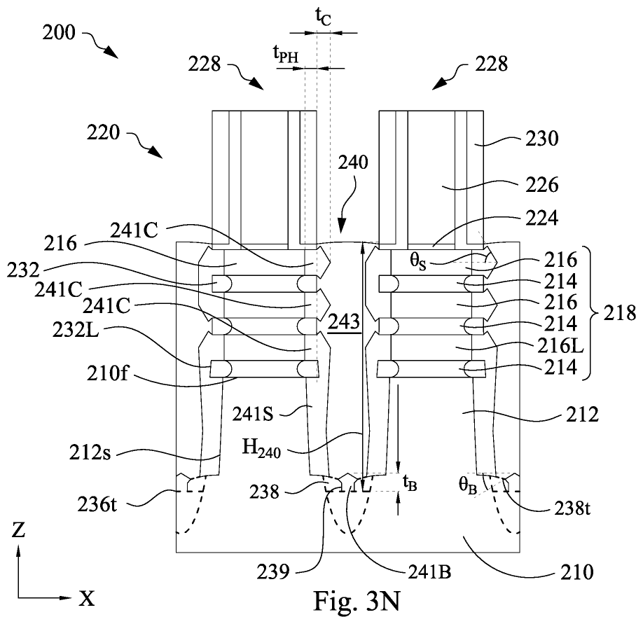

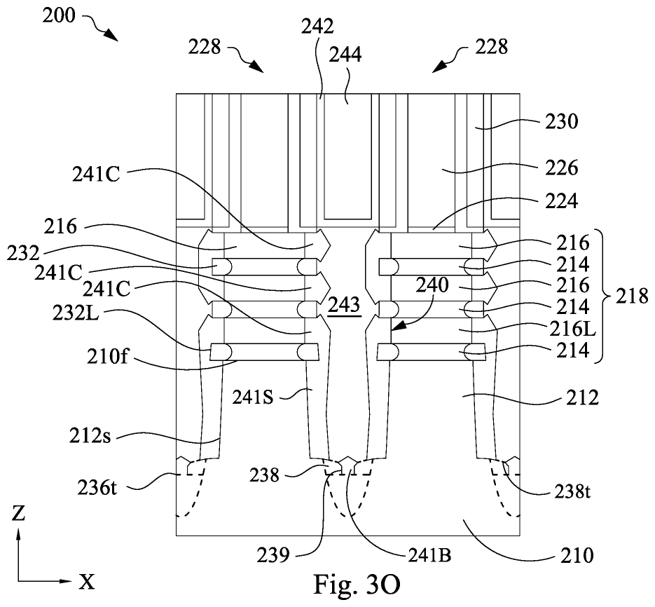

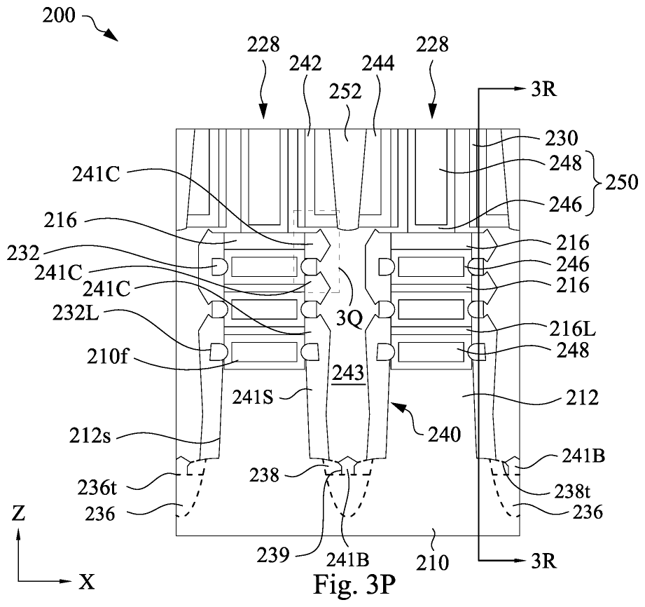

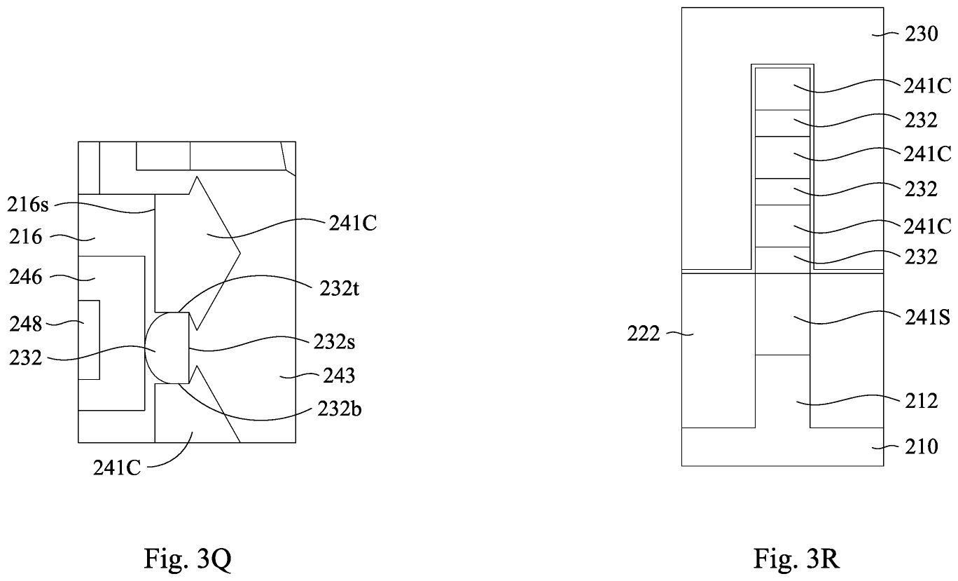

FIG. 2 is a flow chart of a method 100 for manufacturing of a semiconductor device according to embodiments of the present disclosure. FIGS. 3A-3R schematically illustrate various stages of manufacturing a semiconductor device 200 according to embodiments of the present disclosure. The semiconductor device 200 is similar to the semiconductor devices 10 and 10a. Alternatively, the semiconductor devices 10 and 10a may be fabricated using the method 100.

The method 100 begins at operation 102 where a plurality of semiconductor fins 220 are formed over a substrate 210, as shown in FIG. 3A. The substrate 210 is provided to form the semiconductor device 200 thereon. The substrate 210 may include a single crystalline semiconductor material such as, but not limited to Si, Ge, SiGe, GaAs, InSb, GaP, GaSb, InAlAs, InGaAs, GaSbP, GaAsSb, and InP. The substrate 210 may include various doping configurations depending on circuit design. For example, different doping profiles, e.g., n-wells, p-wells, may be formed in the substrate 210 in regions designed for different device types, such as n-type field effect transistors (NFET), and p-type field effect transistors (PFET). In some embodiments, the substrate 210 may be a silicon-on-insulator (SOI) substrate including an insulator structure (not shown) for enhancement.

The substrate 210 has a front surface 210f. A semiconductor stack 218 is then formed over the front surface 210f of the substrate 210. The semiconductor stack includes alternating semiconductor layers made of different materials to facilitate formation of nanosheet channels in a multi-gate device, such as nanosheet channel FETs. In some embodiments, the semiconductor stack includes first semiconductor layers 214 interposed by second semiconductor layers 216. The first semiconductor layers 214 and second semiconductor layers 216 have different oxidation rates and/or etch selectivity. In some embodiments, the front surface 210f of the substrate 210 may have (100) orientation or (110) orientation. The orientation of the front surface 210f determines the orientation of the layers in the semiconductor stack 218, and epitaxial features, such as epitaxial source/drain regions formed from the semiconductor channel layers in the semiconductor stack 218.

In later fabrication stages, portions of the second semiconductor layers 216 form nanosheet channels in a multi-gate device. Three first semiconductor layers 214 and three second semiconductor layers 216 are alternately arranged as illustrated in FIG. 3A as an example. More or less semiconductor layers 214 and 216 may be included in the semiconductor stack depending on the desired number of channels in the semiconductor device to be formed. In some embodiments, the number of semiconductor layers 216 is between 1 and 6.

The semiconductor layers 214, 216 may be formed by a molecular beam epitaxy (MBE) process, a metalorganic chemical vapor deposition (MOCVD) process, and/or other suitable epitaxial growth processes. In some embodiments, the semiconductor layers 216 include the same material as the substrate 210. In some embodiments, the semiconductor layers 214 and 216 include different materials than the substrate 210. In some embodiments, the semiconductor layers 214 and 216 are made of materials having different lattice constants. In some embodiments, the first semiconductor layers 214 include an epitaxially grown silicon germanium (SiGe) layer and the second semiconductor layers 216 include an epitaxially grown silicon (Si) layer. Alternatively, in some embodiments, either of the semiconductor layers 214 and 216 may include other materials such as Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof.

The first semiconductor layers 214 in channel regions may eventually be removed and serve to define a vertical distance between adjacent channels for a subsequently formed multi-gate device. In some embodiments, the thickness of the first semiconductor layer 214 is equal to or greater than the thickness of the second semiconductor layer 216. In some embodiments, each semiconductor layer 214 has a thickness in a range between about 3 nm and about 15 nm. In some embodiments, each second semiconductor layer 216 has a thickness in a range between about 3 nm and about 15 nm. In some embodiments, the second semiconductor layers 216 in the semiconductor stack are uniform in thickness.

The semiconductor fins 220 are formed from the semiconductor stack and a portion of the substrate 210. The semiconductor fins 220 may be formed by patterning a hard mask (not shown) formed on the semiconductor stack and one or more etching processes. Each semiconductor fin 220 has a channel portion 218 formed from the semiconductor layers 214, 216 and a well portion 212 formed from the substrate 210. The semiconductor fins 220 are formed along the X direction.

An isolation layer (not shown, but similar to the isolation layer 22 in FIG. 1B) is formed in the trenches between the semiconductor fins 220. The isolation layer is formed over the substrate 210 to cover the well portion 212 of the semiconductor fins 220. The isolation layer may be formed by a high-density plasma chemical vapor deposition (HDP-CVD), a flowable CVD (FCVD), or other suitable deposition process. In some embodiments, the isolation layer 222 may include silicon oxide, silicon nitride, silicon oxynitride, fluorine-doped silicate glass (FSG), a low-k dielectric, combinations thereof. In some embodiments, the isolation layer is formed to cover the semiconductor fins 220 by a suitable deposition process, such as atomic layer deposition (ALD), and then recess etched using a suitable anisotropic etching process to expose the channel portions 218 of the semiconductor fins 220.

In operation 104, sacrificial gate structures 228 and spacer layers 230 are then formed over the semiconductor fins 220, as shown in FIG. 3A. A sacrificial gate dielectric layer 224 is deposited over the exposed surfaces of the semiconductor device 200. The sacrificial gate dielectric layer 224 may be formed conformally over the semiconductor fins 220, and the isolation layer 222. In some embodiments, the sacrificial gate dielectric layer 224 may be deposited by a CVD process, a sub-atmospheric CVD (SACVD) process, a FCVD process, an ALD process, a PVD process, or other suitable process. The sacrificial gate dielectric layer 224 may include one or more layers of dielectric material, such as SiO₂, SiN, a high-K dielectric material, and/or other suitable dielectric material.

A sacrificial gate electrode layer 226 is deposited over the sacrificial gate dielectric layer 224. The sacrificial gate electrode layer 226 may be blanket deposited on the over the sacrificial gate dielectric layer 224. The sacrificial gate electrode layer 226 includes silicon such as polycrystalline silicon or amorphous silicon. In some embodiments, the sacrificial gate electrode layer 226 is subjected to a planarization operation. The sacrificial gate electrode layer 226 may be deposited using CVD, including LPCVD and PECVD, PVD, ALD, or other suitable process. A patterning operation is the performed over the sacrificial gate dielectric layer 224 layer and the sacrificial gate electrode layer 226 to form the sacrificial gate structures 228, which cover formed over portions of the semiconductor fins 220 designed to be channel regions.

Gate sidewall spacers 230 are then formed on sidewalls of each sacrificial gate structures 228. After the sacrificial gate structures 228 are formed, the gate sidewall spacers 230 may be formed by a blanket deposition of an insulating material followed by anisotropic etch to remove insulating material from horizontal surfaces. The gate sidewall spacers 230 may have a thickness in a range between about 3 nm and about 8 nm. In some embodiments, the insulating material of the gate sidewall spacers 230 is a silicon nitride-based material, such as SIN, SiON, SiOCN or SiCN and combinations thereof. In FIG. 3A, the gate sidewall spacers 230 include two layers. In other embodiments, the gate sidewall spacers 230 may be formed from less or more layers of dielectric materials.

In operation 106, the semiconductor fins 220 on opposite sides of the sacrificial gate structure 228 are recess etched, forming source/drain recesses 234 between the neighboring sacrificial gate structures 228, as shown in FIG. 3B. The first semiconductor layers 214 and the second semiconductor layers 216 in the semiconductor fins 220 are etched down on both sides of the sacrificial gate structures 228 using etching operations. In some embodiments, all layers in the semiconductor stack of the semiconductor fins 220 and a portion of the well portions 212 of the semiconductor fins 220 are etched. In some embodiments, suitable dry etching and/or wet etching may be used to remove the first semiconductor layers 214, the second semiconductor layers 216, and the substrate 210.

In some embodiments, the source/drain recesses 234 are deep trenches formed below the top surface 210f of the substrate 210. In some embodiments, the source/drain recess 234 has a drop distance D₂₃₄, which is defined by the distance between the top surface 210f of the substrate 210 or a sheet bottom to a bottom 234b of the source/drain recesses 234. In some embodiments, the drop distance D₂₃₄ is in a range between about 3 nm and about 50 nm.

In operation 108, inner spacers 232 are formed on exposed ends of the first semiconductor layers 214 under the sacrificial gate structures 228, as shown in FIGS. 3C-3E. The first semiconductor layers 214 exposed to the source/drain recesses 234 are first etched horizontally along the X direction to form spacer cavities, as shown in FIG. 3C. In some embodiments, the first semiconductor layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In some embodiments, the amount of etching of the first semiconductor layer 214 is in a range between about 5 nm and about 10 nm along the X direction.

After forming the spacer cavities at opposite ends of the first semiconductor layers 214, the inner spacers 232 can be formed in the spacer cavities by conformally depositing an insulating layer as shown in FIG. 3D. The insulation layer is then partially removed to form the inner spacer 232 as shown in FIG. 3E. The insulating layer can be formed by ALD or any other suitable method. The subsequent etch process removes most of the insulating layer except inside the cavities, resulting in the inner spacers 232. The inner spacers 232 includes two or more segments, alternately stacked with the second semiconductor layers 216.

The inner spacers 232 may be formed from a single layer or multiple layers of dielectric material. In some embodiments, the inner spacers 232 may include one of silicon nitride (SiN) and silicon oxide (SiO₂), SiONC, or a combination thereof. The inner spacer 232 may have a thickness in a range from about 5 nm to about 10 nm along the X direction.

In operation 110, a bottom epitaxial layer 236 is formed in lower portions of the source/drain recesses 234, as shown in FIG. 3F. In some embodiments, the bottom epitaxial layer 236 fills the lower portions of the source/drain recesses 234 to a level below the bottom most semiconductor layer 216L, or the bottom most channel region. In some embodiments, the bottom epitaxial layer 236 fill the source/drain recesses 234 to a level below the bottom most inner spacers 232L. In some embodiment, a front surface 236f may be at a level below the bottom most inner spacers 232L. In some embodiments, the front surface 236f is below the top surface 210f of the substrate 210 and a portion of mesa sidewall 212s is exposed to the source/drain recess 234 after formation of the bottom epitaxial layer 236.

The material and shape of the bottom epitaxial layer 236 may be selected according to achieve one or more purposes. For example, the bottom epitaxial layer 236 may provide crystalline transition from the substrate 210 to the subsequently formed source/drain region with improved adhesion. The bottom epitaxial layer 236 may define a bottom profile and crystalline direction of the subsequently formed source/drain region. In some embodiments, the bottom epitaxial layer 236 may also function as an alignment feature for back side source/drain contacts.

In some embodiments, the bottom epitaxial layer 236 may be formed from a material to have etch selectivity relative to the material of the substrate 210, such as material in the well portion 212 of the semiconductor fin 220. In some embodiments, the bottom epitaxial layer 236 may also have etch selectivity relative to the insulating material in the isolation layer. In some embodiments, the bottom epitaxial layer 236 are formed from a semiconductor material with a high etch selectivity relative to Si. For example, the bottom epitaxial layer 236 are formed are formed from SiGe.

The bottom epitaxial layer 236 may be formed by any suitable method, such as by CVD, CVD epitaxy, molecular beam epitaxy (MBE), or any suitable deposition technique. In some embodiments, the bottom epitaxial layer 236 are formed from undoped SiGe. In some embodiments, the bottom epitaxial layer 236 are formed from undoped SiGe including an atomic concentration of Ge in a range between about 10% and about 100%. Alternatively, the bottom epitaxial layer 236 may include other materials, such as Ge, a compound semiconductor such as SiC, GeAs, GaP, InP, InAs, and/or InSb, an alloy semiconductor such as GaAsP, AlInAs, AlGaAs, InGaAs, GaInP, and/or GaInAsP, or combinations thereof.

In operation 112, a bottom dielectric layer 238 is formed over the bottom epitaxial layer 236, as shown in FIGS. 3G-3H. The bottom dielectric layer 238 is formed on the front surface 236f of the bottom epitaxial layer 236. The bottom dielectric layer 238 may also cover exposed surfaces of the isolation layer. The bottom dielectric layer 238 may include one or more layers of dielectric material. The bottom dielectric layer 238 may provide electrical isolation between the well portion 212 of the substrate 210 and the source/drain regions during operation.

The bottom dielectric layer 238 may be formed by a directional deposition process with bottom up to sidewall growth selectivity. For example, the bottom dielectric layer 238 may be formed by a directional PECVD process. In some embodiments, the bottom dielectric layer 238 may be formed by depositing a conformal dielectric layer over the exposed surface, as shown in FIG. 3G and then selectively removing the conformal dielectric layer from vertical surfaces and outer surfaces, leaving a portion on a bottom of the source/drain recess 234, as shown in FIG. 3H. In some embodiments, the bottom dielectric layer 238 may be formed from any suitable dielectric material, such as silicon nitride containing material, such as SiN, SION, SiOCN, SiOC, SiCN, a metal oxide, such as AIOx, HfOx, or a combination thereof.

In some embodiments, the bottom dielectric layer 238 covers the top surface 236f of the bottom epitaxial layer 236. The vertical location of the bottom dielectric layer 238 depend on the shape and location of the bottom epitaxial layer 236. The bottom dielectric layer 238 may have a thickness over the bottom epitaxial layer 236. In some embodiments, the thickness is in a range between about 0 nm and about 30 nm. In some embodiments, a top surface 238t of the bottom dielectric layer 238 may intersect with the bottom most inner spacer 2321 so that the bottom dielectric layer 238 covers the well portion 212 of the substrate 210 while keeping the bottom most semiconductor layer 216 exposed. In other embodiments, as shown in FIG. 31, the top surface 238t of the bottom dielectric layer 238 is below the top surface 210f of the substrate 210 so that a portion of sidewall 212s remains exposed to the source/drain recesses 234. The shape and location of the bottom dielectric layer 238 may vary according to design.

In operation 114, an opening 239 is formed through the bottom dielectric layer 238 to expose a portion of the bottom epitaxial layer 236, as shown in FIGS. 31-3J. Depending on the design of the device, operation 114 may be omitted. The opening 239 is formed so that a portion of the bottom epitaxial layer 236 can be used as a seed layer during epitaxial growth of the source/drain region.

In some embodiments, the opening 239 may be formed by forming a pattern using photolithography technique and etching through the pattern using suitable etching process. In other embodiments, the opening 239 may be formed by directional etching.

FIG. 3J is a partial enlarged view of the area 3J in FIG. 3H. As shown in FIG. 3J, the opening 239 exposes a portion of the top surface 236t of the bottom epitaxial layer 236 to the source/drain recess 234. During subsequent epitaxial growth, an epitaxial layer may grow from the top surface 236t and fill the opening 239. In the example of FIG. 3H, two sidewall portions of the sidewall 212s are also exposed to the source/drain recess 234, and epitaxial features may grow from the sidewalls 212s as well. After operation 114, the bottom dielectric layer 238 partially covers the semiconductor surface below the top surface 210f.

In operation 116, an optional channel push process is performed to etch back edge regions of the semiconductor layers 216 and the sidewalls 212s of the well portion 212, as shown in FIGS. 3K-3L. In some embodiments, the semiconductor layers 216 exposed to the source/drain recesses 234 are etched horizontally along the X direction to form push cavities 216C. In some embodiments, the semiconductor layers 216 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. The push cavities 216C are formed below the sidewall spacers 230 and between the inner spacers 232. In some embodiments, the etching amount of the semiconductor layers 216 along the x-direction is in a range between about 1 nm and about 6 nm. In some embodiments, the semiconductor layers 216 are etched back for an amount without exposing the first semiconductor layers 216 behind the inner spacers 232.

In some embodiments, when sidewalls 212s of the well portion 212 are exposed to the source/drain recess 234, a portion of the well portion 212 may also be etched back during the channel push process forming well cavities 212C. The well cavities 212C are below the lower most inner spacers 232L and above the top surface 238t of the bottom dielectric layer 238.

FIG. 3L is a partial enlarged view of the area 3L in FIG. 3K. As shown in FIG. 3L, after the channel push operation, sidewalls 232s, top surfaces 232t, and bottom surfaces 232b are exposed to the source/drain recess 234. As shown in FIG. 3L, the cavities 216C may have a width W216c along the x-direction. The width W216c may be defined by the distance between a sidewall 216s of the semiconductor layer 216 and the sidewall 232s of the inner spacers 232. In some embodiments, the width W216c in a range between about 1 nm and about 6 nm.

The channel push operation enlarged the source/drain recesses 234, therefore, providing an increased volume for the subsequently formed source/drain region. Alternatively, the channel push operation may be omitted.

In operation 118, a first epitaxial source/drain layer 241 is formed in the source/drain recess 234, as shown in FIG. 3M. In some embodiments, a preclean process may be performed prior to epitaxial growth of the first epitaxial source/drain layer 241. The first epitaxial source/drain layer 241 is formed by an epitaxial growth method using CVD, ALD or molecular beam epitaxy (MBE). The first epitaxial layer 241 is grow from exposed semiconductor surfaces, i.e., the sidewall 216s of the semiconductor layer 216 and the top surface 236t of the bottom epitaxial layer 236. The first epitaxial source/drain layer 241 starts as discreet sections from the exposed semiconductor surfaces. For example, the first epitaxial source/drain layer 241 includes channel sections 241C grown from the sidewall 216s of the semiconductor layer 216, sidewall sections 241S grown from exposed sidewalls, a bottom section 241B grown from the bottom epitaxial layer 236 via the opening 239. The channel sections 241C, sidewall sections 241S and the bottom section 241B are correctively referred to as the first epitaxial source/drain layer 241.

The first epitaxial source/drain layer 241 is grown to a desired thickness to enable quality crystalline growth in the subsequent bulk epitaxial growth. After operation 118, the channel sections 241C, sidewall sections 241S and the bottom section 241B may remain discreet or become merged. For example, in FIG. 3M, neighboring channel sections 241C may be merged or the lower most channel section 241C may merge with the sidewall section 241S. Alternatively, the bottom section 241B may merge with the sidewall sections 241S.

The channel sections 241C, sidewall sections 241S and the bottom section 241B may have different physical characters, such as thickness, shape, or surface orientation, because of the different surface orientation, material and/or location of the corresponding seed layers.

In some embodiments, the channel sections 241C may have a channel thickness t_{c}, which is defined by a distance from the thickest portion of the channel section 241C to the sidewall 232s of the inner spacer 232. In some embodiments, the channel thickness t_{c} is in a range between about 1 nm and about 8 nm. In some embodiments, when the channel push operation is performed, the channel portion 241C further includes a push thickness t_{PH} defined by the distance between the sidewall 232s of the inner spacer 232 and the sidewall 216s of the semiconductor layer 216. In some embodiments, the push thickness t_{PH} is in a range between about 1 nm and about 6 nm. In some embodiments, a top surface 241Ct of the channel section 241C may be at an angle θs relative to a horizontal plane. The angle θs reflects a surface orientation which is result of the seed layer surface orientation and process parameter. In some embodiments, the angle θs is in a range between about 10* and about 80*.

In some embodiments, the bottom sections 241B may have a bottom thickness t_{B}, which is defined by a distance from the thickest portion of the bottom section 241B to the top surface 236t of the bottom epitaxial layer 236. In some embodiments, the bottom thickness tₛ is in a range between about 1 nm and about 12 nm. In some embodiments, a top surface 241Bt of the bottom section 241B may be at an angle θB relative to a horizontal plane. The angle θB reflects a surface orientation which is result of the seed layer surface orientation and process parameter. In some embodiments, the angle θB is in a range between about 10* and about 80*.

The first epitaxial source/drain layer 241 may include one or more layers of Si, SiP, SiC and SiCP for NFET or Si, SiGe, Ge for a PFET. For the PFET, p-type dopants, such as boron (B), may also be included in the first epitaxial source/drain layer 241. For NFET, n-type dopants, such as arsenic (As), phosphorous (P), or carbon (C), or combinations thereof, may also be included in the first epitaxial source/drain layer 241.

In some embodiments, the semiconductor device 200 is a p-type device and the first epitaxial source/drain layer 241 includes Si or SiGe with a p-type dopant, such as B or Ga. In some embodiments, the first epitaxial source/drain layer 241 may be a SiGe layer with an atomic concentration of Ge in a range between about 0% and about 40%. In some embodiments, the first epitaxial source/drain layer 241 includes p-type dopants at a concentration between about 1E20 to about 2E21.

In some embodiments, the first epitaxial source/drain layer 241 may be formed by an epitaxial growth method using CVD, ALD or molecular beam epitaxy (MBE). In some embodiments, the epitaxial deposition process may be performed in a temperature range between about 400° C. and about 750° C., for example, between about 520° C. and about 620° C. In some embodiments, the epitaxial deposition process may be performed at a pressure in a range between about 10 torr and about 300 torr, for example, between about 20 torr and about 100 torr. In some embodiments, the epitaxial deposition process may use a precursor, such as H₂SiC₁₂ (DCS), SiH₄, Si₂H₆, GeH₄, GeCl₄, HCl, Cl₂. In some embodiments, a p-type dopant precursor, such as B₂H₆, BCl₃, and Ga(CH₃)₃, may be used during deposition.

In operation 120, a bulk epitaxial source/drain layer 243 is formed over the first epitaxial source/drain layer 241, as shown in FIG. 3N. The bulk epitaxial source/drain layer 243 fills the source/drain recess 234. The first epitaxial source/drain layer 241 and the bulk epitaxial source/drain layer 243 form epitaxial source/drain regions 240. Even though only one layer in FIG. 3N, the bulk epitaxial source/drain layer 243 may include two or more layers.

The bulk epitaxial source/drain layer 243 is epitaxially grown from the first epitaxial source/drain layer 241. The bulk epitaxial source/drain layer 243 has a higher concentration of dopants than the first epitaxial source/drain layer 241. In some embodiments, composition of the bulk epitaxial source/drain layer 243 is also different from the first epitaxial source/drain layer 241. The bulk epitaxial source/drain layer 243 and the first epitaxial source/drain layer 241 have different crystalline structures. The bulk epitaxial source/drain layer 243 may include one or more layers of Si, SiP, SiC and SiCP for NFET or Si, SiGe, Ge for a PFET. For the PFET, p-type dopants, such as boron (B), are also included in the bulk epitaxial source/drain layer 243. For NFET, n-type dopants, such as arsenic (As), phosphorous (P), or carbon (C), or combinations thereof, are included in the bulk epitaxial source/drain layer 243.

In some embodiments, the semiconductor device 200 is a p-type device and the bulk epitaxial source/drain layer 243 includes Si or SiGe with a p-type dopant, such as B or Ga. In some embodiments, the bulk epitaxial source/drain layer 243 may be a SiGe layer with an atomic concentration of Ge in a range between about 20% and about 70%. In some embodiments, the bulk epitaxial source/drain layer 243 includes p-type dopants at a concentration between about 1E20 to about 3E21.

In some embodiments, the bulk epitaxial source/drain layer 243 may be formed by an epitaxial growth method using CVD, ALD or molecular beam epitaxy (MBE). In some embodiments, the epitaxial deposition process may be performed in a temperature range between about 400° C. and about 750° C., for example, between about 520° C. and about 620° C. In some embodiments, the epitaxial deposition process may be performed at a pressure in a range between about 10 torr and about 300 torr, for example, between about 20 torr and about 100 torr. In some embodiments, the epitaxial deposition process may use a precursor, such as H₂SiC₁₂ (DCS), SiH₄, Si₂H₆, GeH₄, GeCl₄, HCl, Cl₂. In some embodiments, a p-type dopant precursor, such as B₂H₆, BCl₃, and Ga(CH₃)₃, may be used during deposition.

As shown in FIG. 3N, the epitaxial source/drain regions 240 are grown pass the topmost semiconductor channel, i.e., the second semiconductor layer 216 under the sacrificial gate structure 228, to be in contact with the gate sidewall spacers 230. The first semiconductor layers 214 under the sacrificial gate structure 228 are separated from the epitaxial source/drain regions 240 by the inner spacers 232.

The epitaxial source/drain regions 240 extend below the top surface 210f of the substrate 210 or extend beyond the lower most layer in the semiconductor stack 218, as the epitaxial source/drain regions 240 are grown from the sidewall 212s of the well portion 212 and/or the bottom epitaxial layer 236. The epitaxial source/drain region 240 is in contact with the bottom dielectric layer 238, which in turn provides isolation between the epitaxial source/drain region 240 and the well portion 212.

In operation 122, a contact etch stop layer (CESL) 242 and an interlayer dielectric (ILD) layer 244 are formed over the exposed surfaces as shown in FIG. 3O. The CESL 242 is formed on the epitaxial source/drain regions 240 and the gate sidewall spacers 230. In some embodiments, the CESL 242 has a thickness in a range between about 1 nm and about 15 nm. The CESL 242 may include Si₃N₄, SiON, SiCN or any other suitable material, and may be formed by CVD, PVD, or ALD.

The interlayer dielectric (ILD) layer 244 is formed over the contract etch stop layer (CESL) 242. The materials for the ILD layer 244 include compounds comprising Si, O, C, and/or H, such as silicon oxide, SiCOH and SiOC. Organic materials, such as polymers, may be used for the ILD layer 244. After the ILD layer 244 is formed, a planarization operation, such as CMP, is performed to expose the sacrificial gate electrode layer 226 for subsequent removal of the sacrificial gate structures 228. The ILD layer 244 protects the epitaxial source/drain regions 240 during the removal of the sacrificial gate structures 228.

In operation 124, replacement gate structures 250 are formed in place of the sacrificial gate structures 228, as shown in FIGS. 3P, 3Q and 3R. The sacrificial gate structures 228 are first removed. Particularly, the sacrificial gate electrode layer 226 and the sacrificial gate dielectric layer 224 are removed sequentially to expose the channel portion 218. The first semiconductor layers 214 and the second semiconductor layers 216 are exposed. The first semiconductor layers 214 are then selectively removed using an etchant with a higher etch rate with respect to the first semiconductor layers 214 than the etch rate with respect to the second semiconductor layers 216. After the first semiconductor layers 214 are removed, the second semiconductor layers 216 are exposed resulting in a semiconductor channel region including the second semiconductor layers 216 in connection to the epitaxial source/drain regions 240.

The replacement gate structures 250 are then formed around the channel region. A gate dielectric layer 246 is formed around each of the second semiconductor layers 216 and a gate electrode layer 248 is formed on the gate dielectric layer 246. The gate dielectric layer 246 and the gate electrode layer 248 may be referred to as a replacement gate structure 250.

The gate dielectric layer 246 may be formed by CVD, ALD or any suitable method. In one embodiment, the gate dielectric layer 246 is formed using a highly conformal deposition process such as ALD in order to ensure the formation of a gate dielectric layer 246 having a uniform thickness around each of the second semiconductor layers 216. In some embodiments, the thickness of the gate dielectric layer 246 is in a range between about 1 nm and about 6 nm.

The gate dielectric layer 246 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HTIO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, an interfacial layer (not shown) is formed between the second semiconductor layer 16 and the gate dielectric layer 246. In some embodiments, one or more work function adjustment layers (not shown) are interposed between the gate dielectric layer 246 and the gate electrode layer 248.

The gate electrode layer 248 is formed on the gate dielectric layer 246 to surround each of the second semiconductor layer 216 (i.e., each channel) and the gate dielectric layer 246. The gate electrode layer 248 includes one or more layers of conductive material, such as polysilicon, aluminum, copper, titanium, tantalum, tungsten, cobalt, molybdenum, tantalum nitride, nickel silicide, cobalt silicide, TiN, WN, TiAI, TiAIN, TaCN, TaC, TaSiN, metal alloys, other suitable materials, and/or combinations thereof. The gate electrode layer 248 may be formed by CVD, ALD, electro-plating, or other suitable method.

After the formation of the gate electrode layer 248, a planarization process, such as a CMP process, is performed to remove excess deposition of the gate electrode material and expose the top surface of the ILD layer 244. In some embodiments, source/drain contacts 252 are formed in the ILD layer 244. Prior to forming the front side source/drain contacts 252, contact holes are formed in the ILD layer 244, the CESL 242, and a portion of the epitaxial source/drain regions 240.

After formation of the front side source/drain contacts 252 are formed, a front side interconnect structure (not shown) is formed by a middle end of line process. The front side interconnect structure includes multiple dielectric layers having metal lines and vias formed therein. The metal lines and vias in the front side interconnect structure may be formed of copper or copper alloys using one or more damascene processes. The front side interconnect structure may include multiple sets of interlayer dielectric (ILD) layers and inter-metal dielectrics (IMDs) layers.

FIG. 3Q is a partial enlarged view of FIG. 3P in the area marked by 3Q in FIG. 3P. FIG. 3R is a partial cross sectional view of the semiconductor device 200 along the 3R-3R line in FIG. 3P. As shown in FIGS. 3Q and 3P, the inner spacers 232 is in contact with channel sections 241C of the first epitaxial layer 241 at the top surface 232t and the bottom surface 232b. The sidewall 232s of the inner spacer 232 is in contact with the epitaxial source/drain region 240, which may be channel sections 241C or the bulk epitaxial source/drain layer 243.

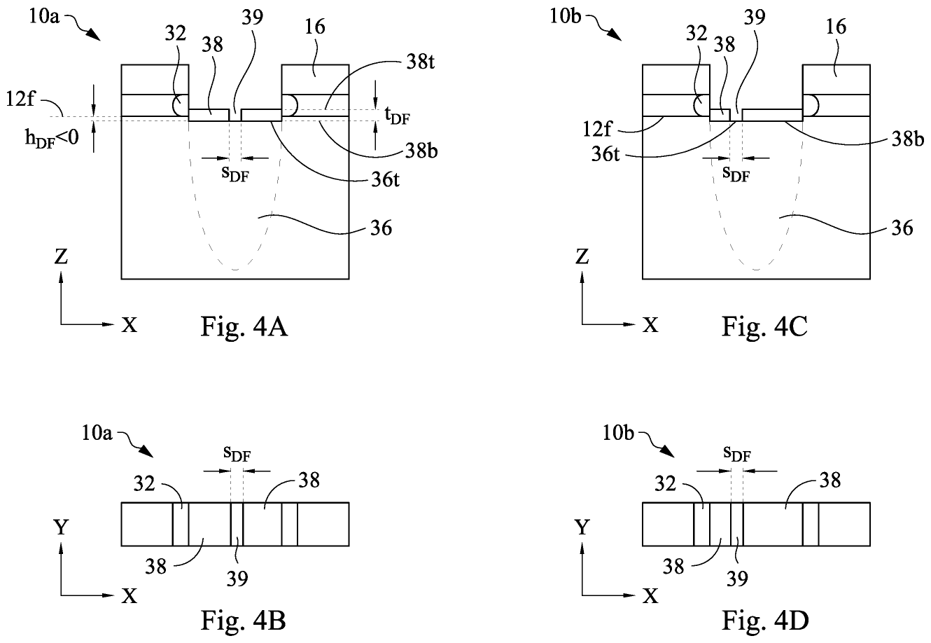

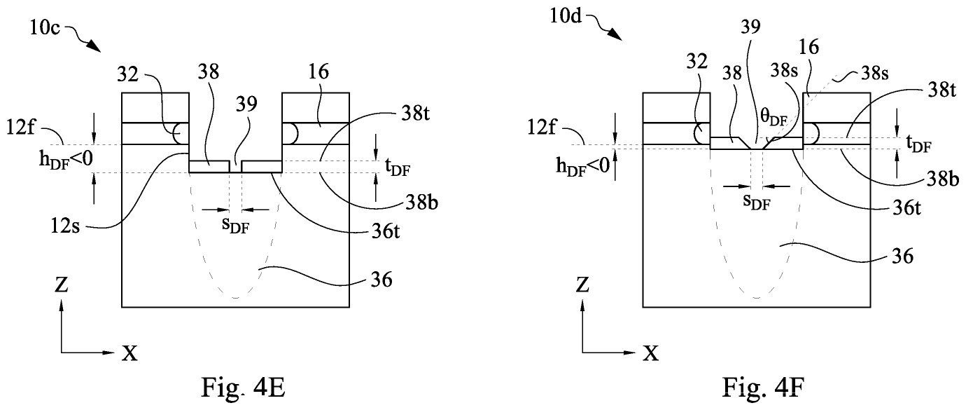

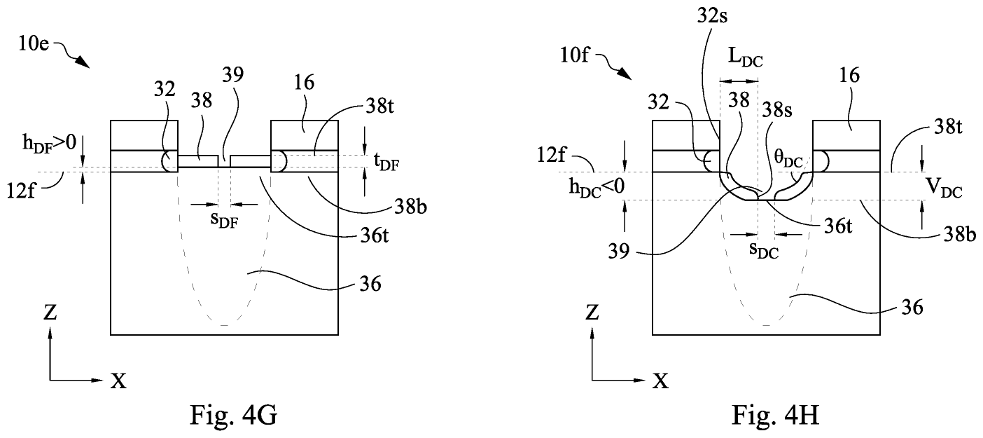

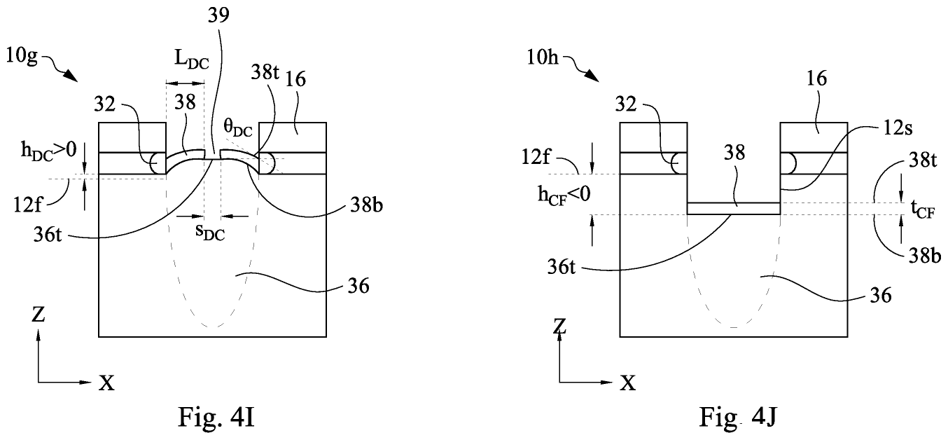

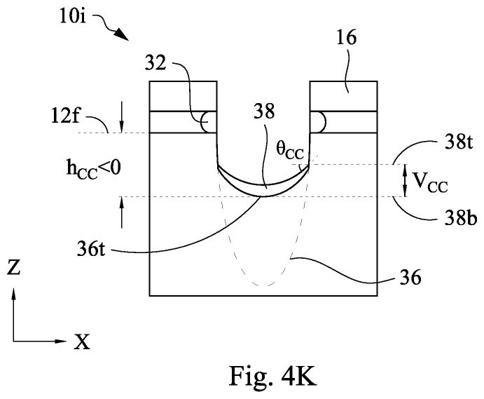

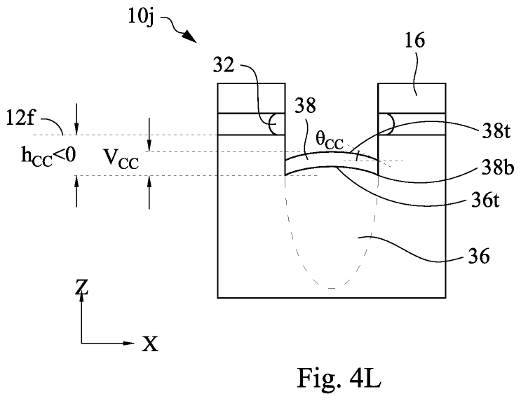

The bottom dielectric layer according to the present disclosure, such as the bottom dielectric layer 238, may be vary in shape and/or location to achieve various design effects. The bottom dielectric layer may be formed at different locations relative to the channel layers and/or have different shapes. FIGS. 4A-4L include various arrangement of the bottom dielectric layer according to embodiments of the present disclosure.

FIGS. 4A-4B schematically demonstrate a semiconductor device 10a according to the present disclosure. FIG. 4A is a schematic cross sectional view of the semiconductor device 10a after operation 114. FIG. 4B is a corresponding top view of the semiconductor device 10a. In FIG. 4A, the bottom epitaxial layer 36 has a substantially flat top surface 36t resulting in a substantially flat bottom dielectric layer 38. The bottom dielectric layer 38 may have a thickness t_{DF} in a range between about 1 nm and about 10 nm. The bottom dielectric layer 36 may be positioned substantially near the sheet bottom or the top surface 12f of the substrate 12. The relative position between the bottom dielectric layer 38 and the top surface 12f may be denoted by a drop distance h_{DF}, which is defined by the distance between the bottom surface 38b of the bottom dielectric layer 38 and the sheet bottom or the top surface 12f. In some embodiments, the drop distance h_{DF} is in a range between about −15 nm and about 15 nm. A positive drop distance h_{DF} indicates that the bottom surface 38b of the bottom dielectric layer 38 is above the sheet bottom or the top surface 12f while a negative drop distance h_{DF} indicates that the bottom surface 38b of the bottom dielectric layer 38 is below the sheet bottom or the top surface 12f. In FIG. 4A, the drop distance hpF is negative.

The opening 39 through the bottom dielectric film 39 is wide enough to grow the epitaxial source/drain region from the bottom epitaxial layer 38 through the opening 39. As shown in FIG. 4B, the opening 39 extends across the bottom dielectric layer 38 along the y direction dividing the bottom dielectric layer 38 into two discontinuous portions. In some embodiments, a width S_{DF} of the opening 39 is in a range between about 1 nm and about 30 nm.

FIGS. 4C-4D schematically demonstrate a semiconductor device 10b according to the present disclosure. The semiconductor device 10b is similar to the semiconductor device 10a except that the opening 39 is asymmetrically positioned relative to the inner spacers 32.

FIG. 4E schematically demonstrates a semiconductor device 10c according to the present disclosure. The semiconductor device 10c is similar to the semiconductor device 10a except that the bottom dielectric layer 38 in the semiconductor device 10c is lower along the z-direction, i.e., with a greater negative drop distance h_{DF}. The greater negative drop distance h_{DF} results in a portion of the sidewall 12s of the mesa portion 12M is exposed to the source/drain recess 34. The exposed sidewall 12s functions as a seed layer during the subsequent growth of the source/drain region 40 to achieve certain structure in the source/drain region. Lowering the bottom dielectric layer 38 also increases volume of the source/drain region 40.

FIG. 4F schematically demonstrates a semiconductor device 10d according to the present disclosure. The semiconductor device 10f is similar to the semiconductor device 10a except that sidewalls 38s of the opening 38 are slanted. The sidewall 38s and the top surface 38t form an angle θ_{DF}. In some embodiments, the angle θ_{DF} is in a range between about 10° and about 150°. Suitable angle θ_{DF} may be selected to achieve desired crystalline structure.

FIG. 4G schematically demonstrates a semiconductor device 10e according to the present disclosure. The semiconductor device 10f is similar to the semiconductor device 10a except that the bottom dielectric layer 38 in the semiconductor device 10f is higher along the z-direction, i.e., with a positive drop distance h_{DF}. The positive drop distance huff results in an improved isolation between the mesa portion 12M and the epitaxial source/drain region 40 to be formed over the bottom dielectric layer 38.

FIG. 4H schematically demonstrates a semiconductor device 10f according to the present disclosure. The semiconductor device 10f is similar to the semiconductor device 10a except that the bottom epitaxial layer 36 has a curved top surface 36t resulting in a substantially curved bottom dielectric layer 38. The bottom dielectric layer 38 may have a vertical stretch V_{DC}, which is defined by a distance between the highest point of the top surface 38t and the lowest point of the bottom surface 38b along the z-direction. In some embodiments, the vertical stretch V_{DC} is in a range between about 1 nm and about 30 nm. The bottom dielectric layer 38 may have a horizontal stretch L_{DC}, which is defined by a distance between the sidewall 32s of the inner spacer 32 and the sidewall 38s of the opening 39 along the x-direction. In some embodiments, the horizontal stretch L_{DC} is in a range between about 1 nm and about 20 nm. In some embodiments, the bottom dielectric layer 38 and a x-y plane may form an angel θ_{DC}. In some embodiments, the angle θ_{DC} is in a range between about 5° and about 90°. The relative position between the bottom dielectric layer 38 and the top surface 12f may be denoted by a drop distance hpc, which is defined by the distance between the lowest point of the bottom dielectric layer 38 and the sheet bottom or the top surface 12f along the z-direction. In some embodiments, the drop distance hoc is in a range between about −15 nm and about 15 nm. In FIG. 4H, the drop distance hoc is negative. In FIG. 4H, the top surface 36t of the bottom epitaxial layer 36 and the bottom dielectric layer 38 are both concave.

The opening 39 through the bottom dielectric film 39 is wide enough to grow the epitaxial source/drain region from the bottom epitaxial layer 38 through the opening 39. The opening 39 extends across the bottom dielectric layer 38 along the y direction dividing the bottom dielectric layer 38 into two discontinuous portions. In some embodiments, a width Soc of the opening 39 is in a range between about 1 nm and about 30 nm.

FIG. 4I schematically demonstrates a semiconductor device 10g according to the present disclosure. The semiconductor device 10g is similar to the semiconductor device 10f shown in FIG. 4H except that the top surface 36t of the bottom epitaxial layer 36 and the bottom dielectric layer 38 are both convex, and the drop distance hoc is positive.

FIG. 4J schematically demonstrates a semiconductor device 10h according to the present disclosure. The semiconductor device 10h is similar to the semiconductor device 10c shown in FIG. 4E except that the bottom dielectric layer 36 is a continuous layer without any openings. The exposed sidewall 12s functions as a seed layer when forming the epitaxial source/drain region 40. The bottom dielectric layer 38 may have a thickness t_{CF} in a range between about 1 nm and about 10 nm. The bottom dielectric layer 36 may be positioned substantially near the sheet bottom or the top surface 12f of the substrate 12. The relative position between the bottom dielectric layer 38 and the top surface 12f may be denoted by a drop distance h_{CF}, which is defined by the distance between the bottom surface 38b of the bottom dielectric layer 38 and the sheet bottom or the top surface 12f. In some embodiments, the drop distance h_{CF} is in a range between about-20 nm and about 20 nm.

FIG. 4K schematically demonstrates a semiconductor device 10i according to the present disclosure. The semiconductor device 10i is similar to the semiconductor device 10h of FIG. 4J except that the bottom epitaxial layer 36 has a curved top surface 36t resulting in a substantially curved bottom dielectric layer 38. The bottom dielectric layer 38 is a continuous curved film.

The bottom dielectric layer 38 may have a vertical stretch V_{CC}, which is defined by a distance between the highest point of the top surface 38t and the lowest point of the bottom surface 38b along the z-direction. In some embodiments, the vertical stretch V_{CC} is in a range between about 1 nm and about 30 nm. In some embodiments, the bottom dielectric layer 38 and a x-y plane may form an angel θ_{CC}. In some embodiments, the angle θ_{CC} is in a range between about 5° and about 90°. The relative position between the bottom dielectric layer 38 and the top surface 12f may be denoted by a drop distance h_{CC}, which is defined by the distance between the lowest point of the bottom dielectric layer 38 and the sheet bottom or the top surface 12f along the z-direction. In some embodiments, the drop distance h_{CC} is in a range between about-20 nm and about 20 nm.

FIG. 4L schematically demonstrates a semiconductor device 10j according to the present disclosure. The semiconductor device 10j is similar to the semiconductor device 10i shown in FIG. 4L except that the top surface 36t of the bottom epitaxial layer 36 and the bottom dielectric layer 38 are both convex.

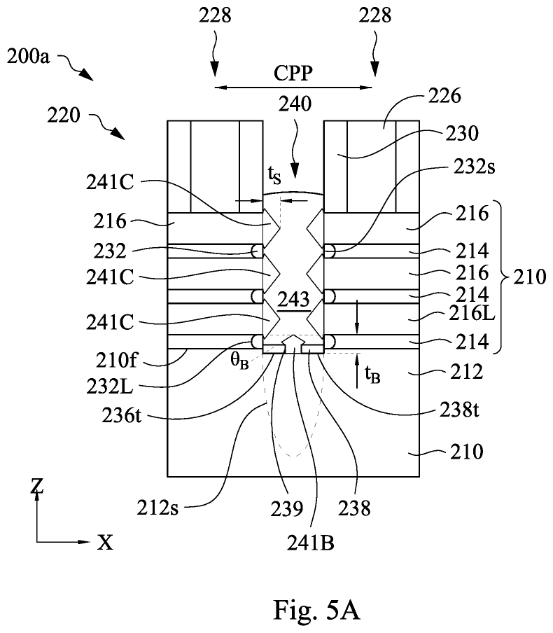

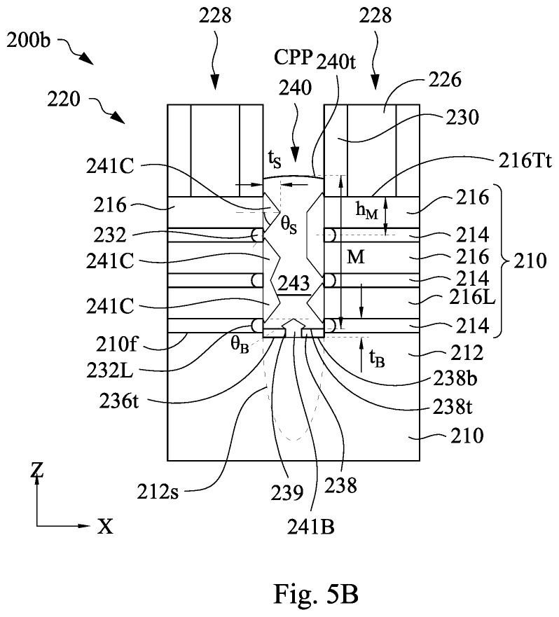

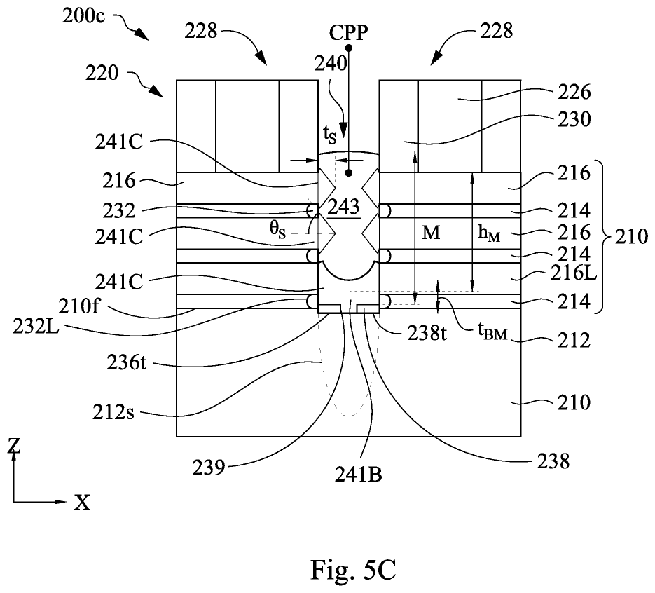

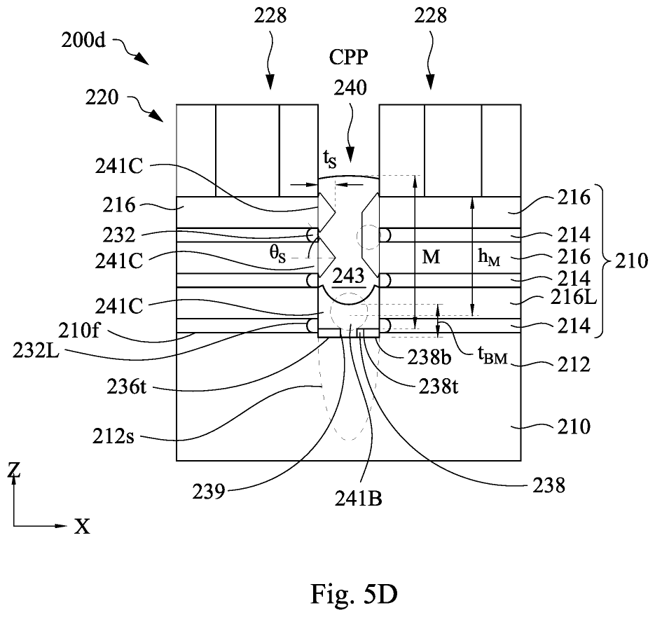

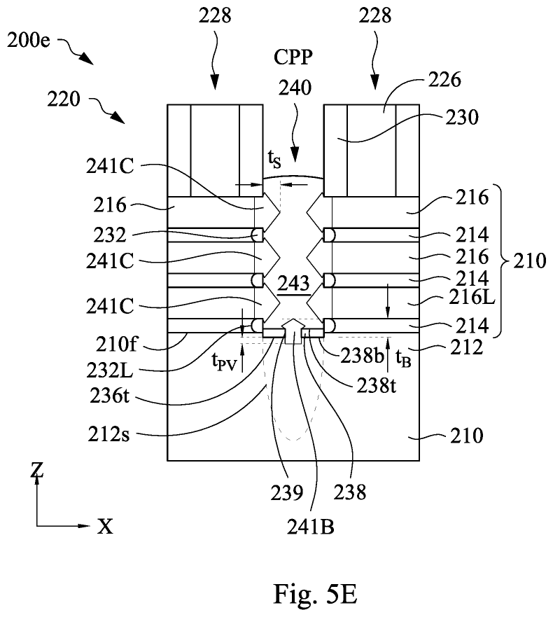

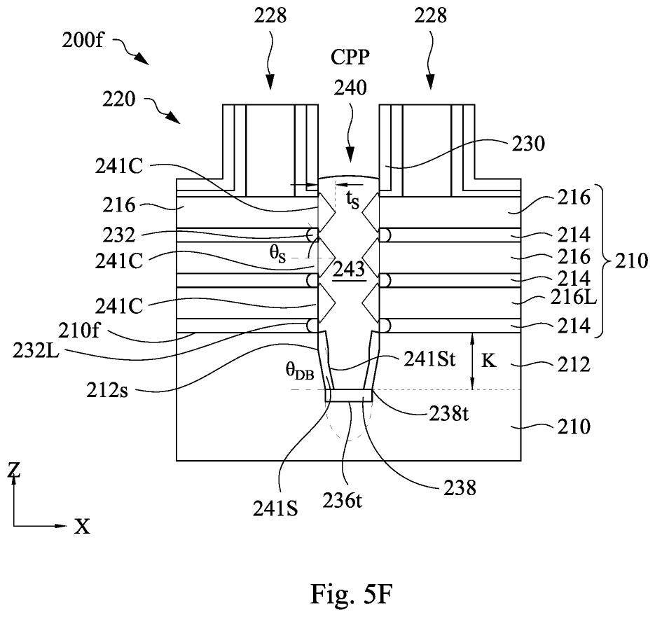

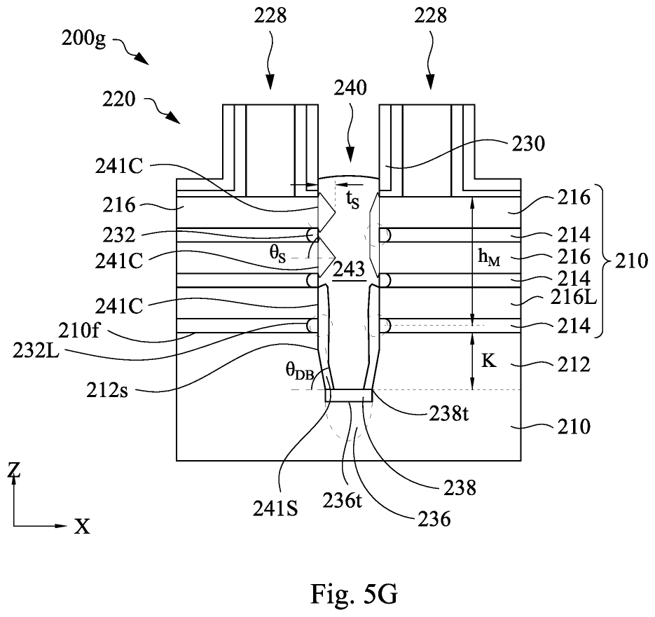

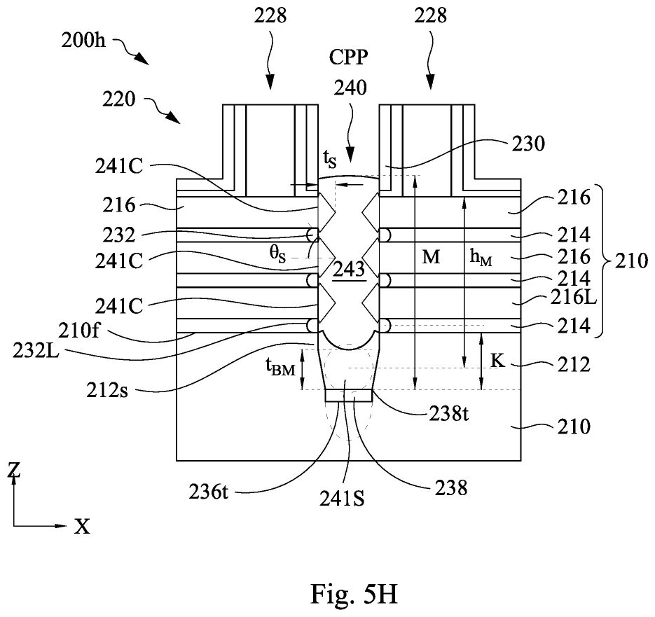

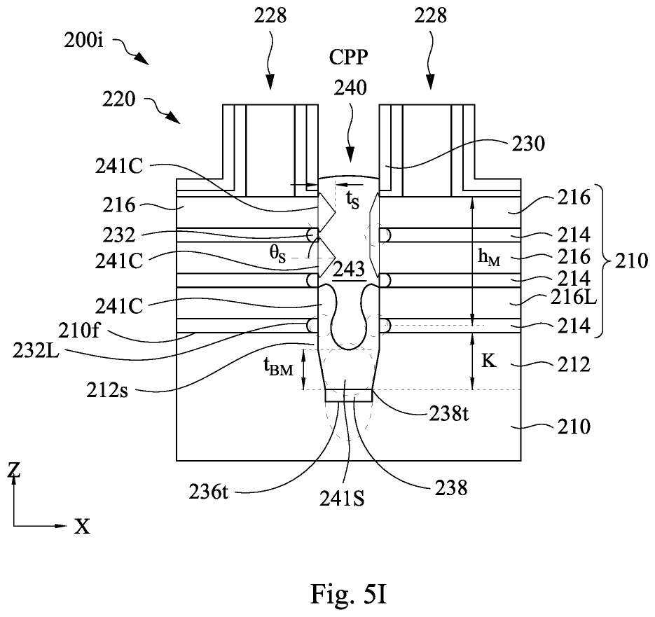

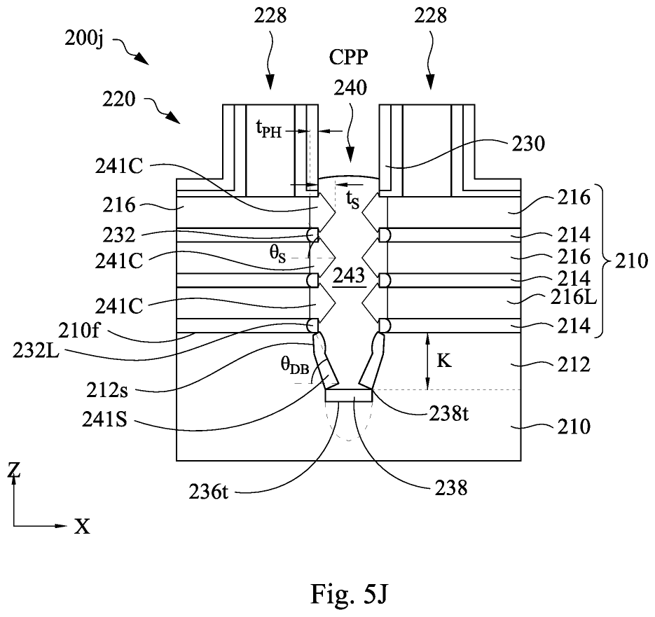

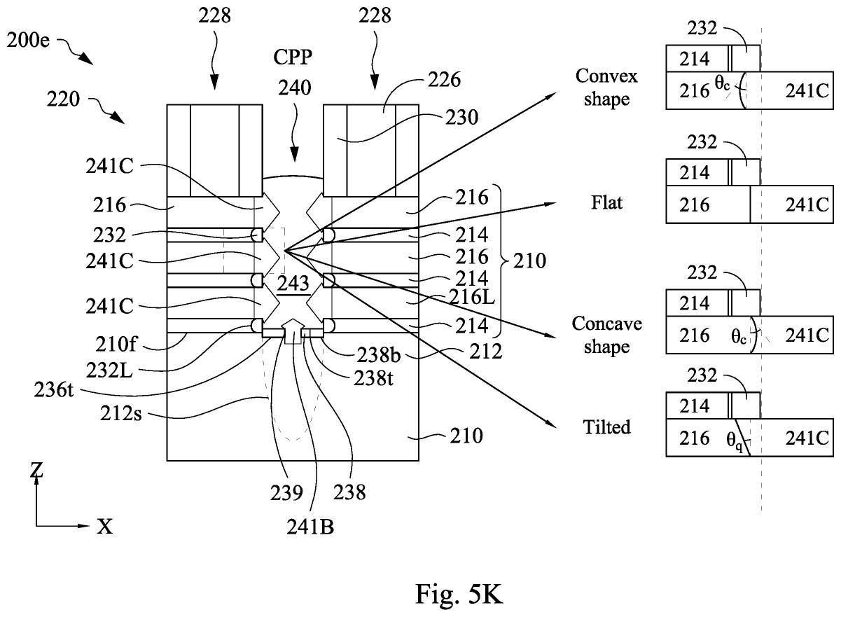

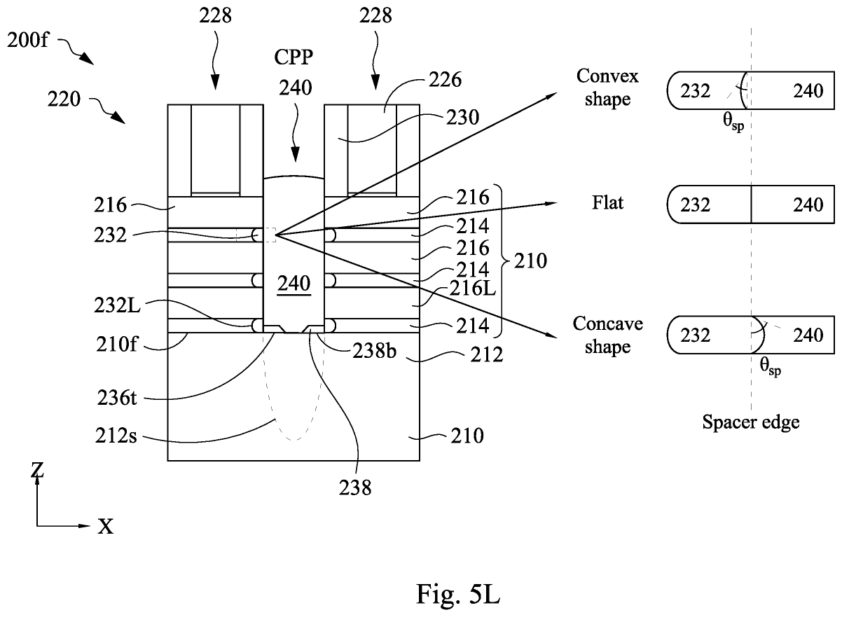

According to embodiments of the present disclosure, source/drain regions may be designed to achieve different shapes and/or layer compositions of the source/drain region. For example, by varying shape and/or position of the bottom dielectric layer, forming or omitting openings through the bottom dielectric layer, selecting shape and location of the opening, with or without channel push process, etc. FIGS. 5A-5L schematically demonstrates various designs of the source/drain regions according to embodiments of the present disclosure.

FIG. 5A schematically demonstrates a semiconductor device 200a according to embodiments of the present disclosure. FIG. 5A schematically demonstrates the semiconductor device 200a after formation of the epitaxial source/drain regions 240, for example, after operation 120. The semiconductor device 200a is similar to the semiconductor device 200 described above, except that the channel push operation 116 is omitted in fabricating the semiconductor device 200a. Additionally, the bottom dielectric layer 238 is in contact with the lowermost inner spacers 232 and the sidewall 212s of the well portion 212 does not contact the epitaxial source/drain region 240. In other words, the bottom dielectric layer 238 isolates the epitaxial source/drain region 240 and the well portion 212 of the substrate 210, or the mesa region.

In the semiconductor device 200a, the first epitaxial source/drain layer 241 includes various discreet sections, i.e., the channel sections 241C and the bottom section 241B, which are not merged with one another. The channel sections 241C extend from the sidewall 232s of the inner spacer 232 for a distance t_{B} along the x-direction. In some embodiments, the distance t_{B} is in arrange between about 1 nm and about 8 nm. The bottom section 241B extends from the top surface 236t for a distance t_{B} along the z-direction. In some embodiments, the distance the is in arrange between about 1 nm and about 12 nm. The bulk epitaxial source/drain layer 243 is in contact with at least of a portion of the sidewalls 232s of the inner spacer 232. The bulk epitaxial source/drain layer 243 is also in contact with the bottom dielectric layer 238.

FIG. 5B schematically demonstrates a semiconductor device 200b according to embodiments of the present disclosure. The semiconductor device 200b is similar to the semiconductor device 200a described above, except that some channel sections 241C of the first epitaxial source/drain layer 241 are merged with each other while other channel sections 241 remain unmerged. The epitaxial source/drain region 240 has an EPI height M, which may be defined as a distance between a top surface 240t and a bottom surface 240b of the epitaxial source/drain region 240 along the z-direction. In some embodiments, the EPI height is in a range between about 20 nm and about 105 nm. In some embodiments, the channel sections 241C may merge at a merge height h_{M}, which may be defined at a distance between the top surface 240t of the epitaxial source/drain region 240 and a merging point along the z-direction. In some embodiments, the merge height h_{M} is in a range between 0 and the EPI height M. As shown FIG. 5B, in the semiconductor device 200b, the bulk epitaxial source/drain layer 243 is in contact with some of the inner spacers 232, but a portion of the inner spacers 232 may be covered by the first epitaxial source/drain layer 241. The bulk epitaxial source/drain layer 243 is also in contact with the bottom dielectric layer 238.

FIG. 5C schematically demonstrates a semiconductor device 200c according to embodiments of the present disclosure. The semiconductor device 200c is similar to the semiconductor device 200a described above, except that the lowermost channel section 241C and the bottom section 241B of the first epitaxial source/drain layer 241 are merged together while upper channel sections 241 remain unmerged. As shown FIG. 5C, in the semiconductor device 200c, the bulk epitaxial source/drain layer 243 is in contact with the upper inner spacers 232, but the lower most inner spacers 232 and the bottom dielectric layer 238 are covered by the first epitaxial source/drain layer 241.

FIG. 5D schematically demonstrates a semiconductor device 200d according to embodiments of the present disclosure. The semiconductor device 200d is similar to the semiconductor device 200c described above, except that some of the upper channel sections 241 are merged with each other. As shown FIG. 5D, in the semiconductor device 200d, the bulk epitaxial source/drain layer 243 is in contact with some of the upper inner spacers 232, but the lower most inner spacers 232 and the bottom dielectric layer 238 are covered by the first epitaxial source/drain layer 241.

FIG. 5E schematically demonstrates a semiconductor device 200e according to embodiments of the present disclosure. The semiconductor device 200e is similar to the semiconductor device 200a described above, except that a channel push operation is performed during fabrication of the semiconductor device 200e. As a result, the epitaxial source/drain region 240 extends into the semiconductor layers 216, or the channel layers, beyond the sidewalls 232s of the inner spacers 232. The first epitaxial source/drain layer 241 may extend a length t_{PH} from the sidewall 232s of the inner spacer 232. In some embodiments, the length t_{PH} is in a range between about 1 nm and about 6 nm. As discussed above, the channel section 241C of the first epitaxial source/drain layer 241 may extend from the sidewall 232s of the inner spacers 232 for a distance tₛ. In some embodiments, the total thickness tₛ+t_{PH} of the channel section 241C of the first epitaxial source/drain layer 241 is in a range between about 1 nm and about 14 nm.

In the embodiments, the bottom epitaxial layer 236 is also etched back during the channel push operation. As a result, the epitaxial source/drain region 240 extends through the bottom dielectric layer 238 and into the bottom epitaxial layer 236. In some embodiments, the epitaxial source/drain region 240 may extend a length t_{PV} from the top surface 236t into the bottom epitaxial layer 236. In some embodiments, the length t_{PV} is in a range between about 1 nm and about 10 nm. As discussed above, the bottom section 241B of the first epitaxial source/drain layer 241 may extend from the top surface 236t for a distance t_{B}. In some embodiments, the total thickness t_{B}+t_{PV} of the bottom section 241B of the first epitaxial source/drain layer 241 is in a range between about 1 nm and about 22 nm.

FIG. 5F schematically demonstrates a semiconductor device 200f according to embodiments of the present disclosure. The semiconductor device 200f is similar to the semiconductor device 200 described above, except that the channel push operation 116 is omitted in fabricating the semiconductor device 200f. Additionally, the bottom dielectric layer 238 is a continuous layer without the opening 239. In some embodiments, the sidewall 212s of the well portion 212 is in contact with the epitaxial source drain region 240 for a vertical length K. In some embodiments, the vertical length K is in a range between about 0 nm and about 50 nm. In the semiconductor device 200f, the first epitaxial source/drain layer 241 includes various discreet sections, i.e., the channel sections 241C and the sidewall section 241S, which are not merged with one another. The sidewall section 241S is grown from the exposed sidewalls 212s. In some embodiments, a top surface 241st of the sidewall section 241S and a x-y plane form an angle θ_{DB}. In some embodiments, the angle θ_{DB} is in a range between about 10° and about 80°. The bulk epitaxial source/drain layer 243 is in contact with at least of a portion of the sidewalls 232s of the inner spacer 232. The bulk epitaxial source/drain layer 243 is also in contact with the bottom dielectric layer 238.

FIG. 5G schematically demonstrates a semiconductor device 200g according to embodiments of the present disclosure. The semiconductor device 200g is similar to the semiconductor device 200 described above, except that the channel push operation 116 is omitted in fabricating the semiconductor device 200g. Additionally, the bottom dielectric layer 238 is a continuous layer without the opening 239. The first epitaxial source/drain layer 241 covers the sidewall 232s of some of the inner spacers 232. The bulk epitaxial source/drain layer 243 is in contact with at least of a portion of the sidewalls 232s of the inner spacer 232. The bulk epitaxial source/drain layer 243 is also in contact with the bottom dielectric layer 238.

FIG. 5H schematically demonstrates a semiconductor device 200h according to embodiments of the present disclosure. The semiconductor device 200h is similar to the semiconductor device 200g described above, except that the sidewall sections 241S of the first epitaxial source/drain layer 241 are merged together while the channel sections 241 remain unmerged. As shown FIG. 5H, in the semiconductor device 200h, the bulk epitaxial source/drain layer 243 is in contact with the inner spacers 232, but the bottom dielectric layer 238 are covered by the first epitaxial source/drain layer 241.

FIG. 5I schematically demonstrates a semiconductor device 200i according to embodiments of the present disclosure. The semiconductor device 200i is similar to the semiconductor device 200h described above, except that the sidewall sections 241S of the first epitaxial source/drain layer 241 are merged together and with the lowermost channel sections 241C. Some of the upper channel sections 241 remain unmerged. As shown FIG. 5I, in the semiconductor device 200i, the bulk epitaxial source/drain layer 243 is in contact with some of the upper inner spacers 232, but the lower most inner spacers 232 and the bottom dielectric layer 238 are covered by the first epitaxial source/drain layer 241.

FIG. 5J schematically demonstrates a semiconductor device 200j according to embodiments of the present disclosure. The semiconductor device 200j is similar to the semiconductor device 200f described above in FIG. 5F, except that a channel push operation is performed during fabrication of the semiconductor device 200j. As a result, the epitaxial source/drain region 240 extends into the semiconductor layers 216, or the channel layers, beyond the sidewalls 232s of the inner spacers 232. The first epitaxial source/drain layer 241 may extend a length t_{PH} from the sidewall 232s of the inner spacer 232. In some embodiments, the length t_{PH} is in a range between about 1 nm and about 6 nm. As discussed above, the channel section 241C of the first epitaxial source/drain layer 241 may extend from the sidewall 232s of the inner spacers 232 for a distance t_{S}. In some embodiments, the total thickness t_{S}+t_{PH} of the channel section 241C of the first epitaxial source/drain layer 241 is in a range between about 1 nm and about 14 nm. In the embodiments, the well portion 212 is also etched back during the channel push operation. As a result, the sidewall section 241S of the first epitaxial source/drain layer 241 extends beyond the sidewall 232s of the inner spacers 232.

FIG. 5K schematically demonstrates various profiles of the interface between the epitaxial source/drain region 240 and the semiconductor layer 216 or the channel layer. The profile may be convex, flat, concave, or titled. The different profiles may be achieved by controlling the etch back process during the channel push operation, such as operation 116. The interface and the y-z plane form an angle @c. In some embodiments, the angel θ_{C} is in a range between about −80° and about 80°.

FIG. 5L schematically demonstrates various profiles of the interface between the epitaxial source/drain region 240 and the inner spacers 232. The profile may be convex, flat, or concave. The different profiles may be achieved by controlling the etch back process while forming the inner spacers 232. The interface and the y-z plane form an angle θ_{SP}. In some embodiments, the angel θ_{SP} is in a range between about −80° and about 80°.

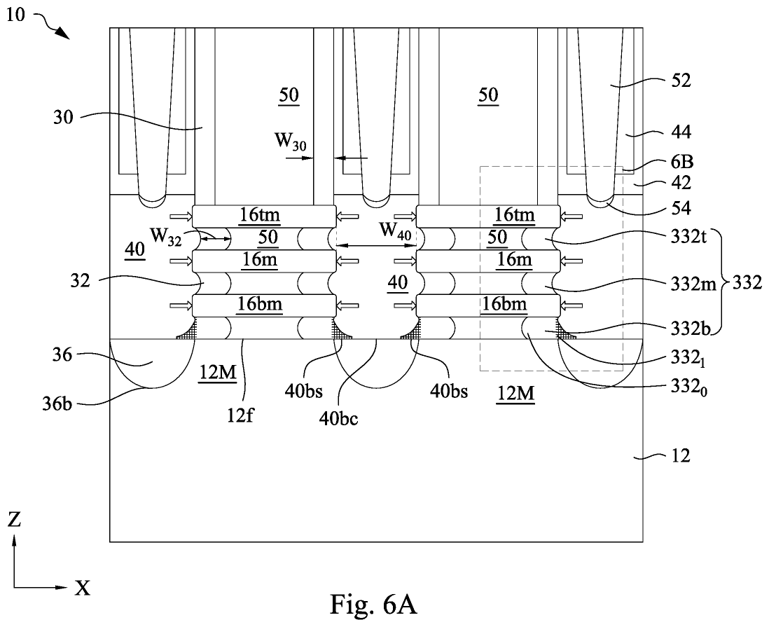

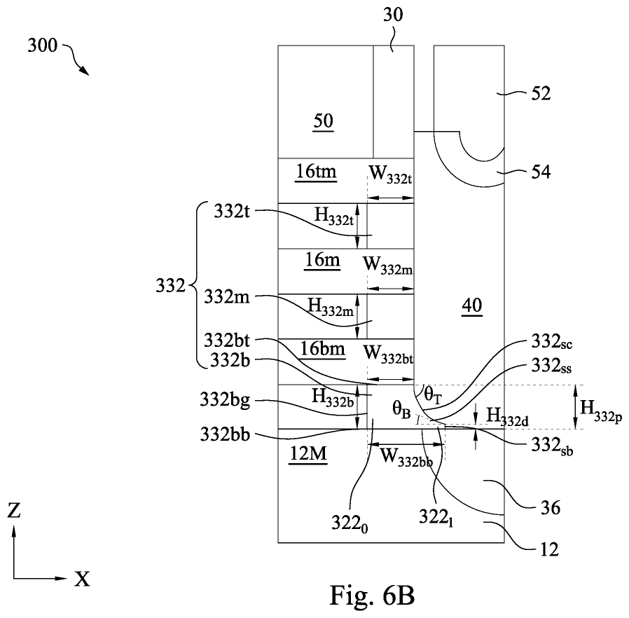

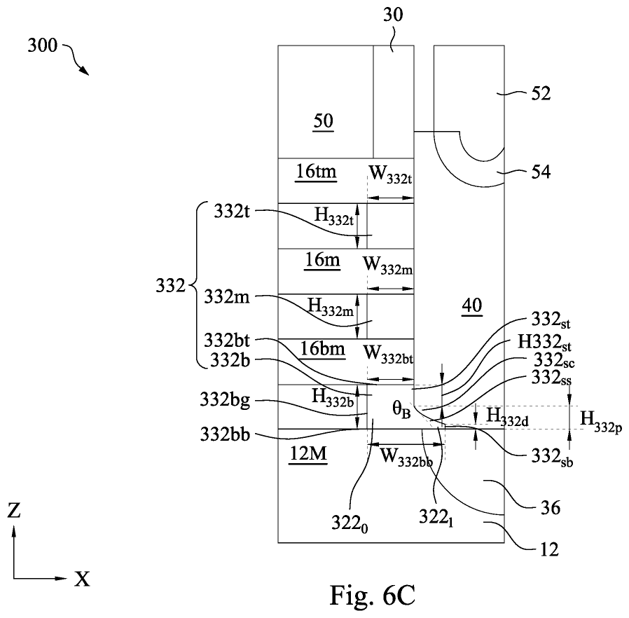

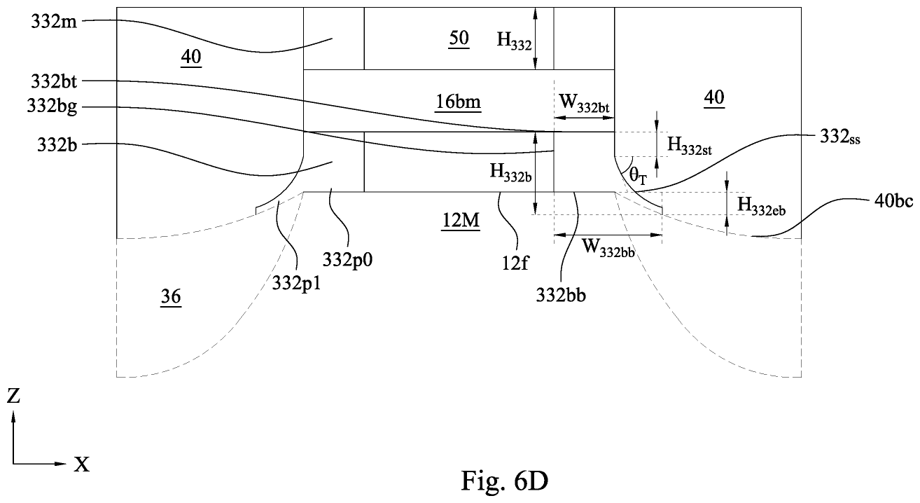

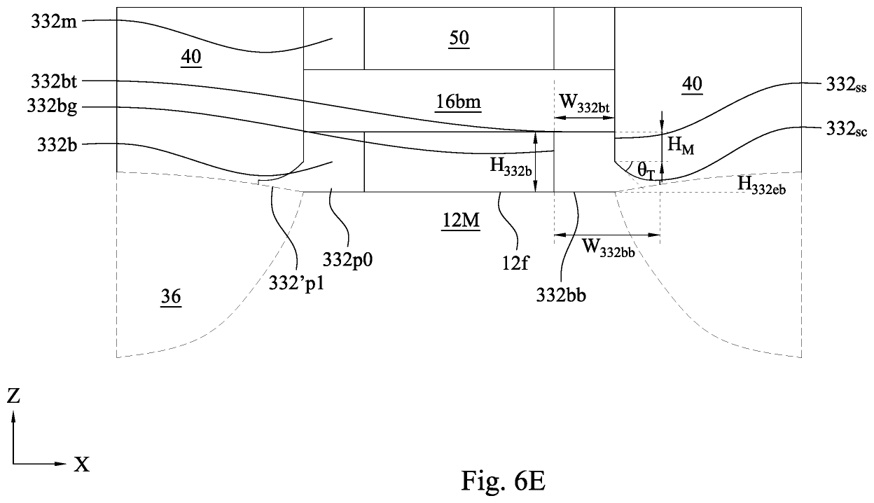

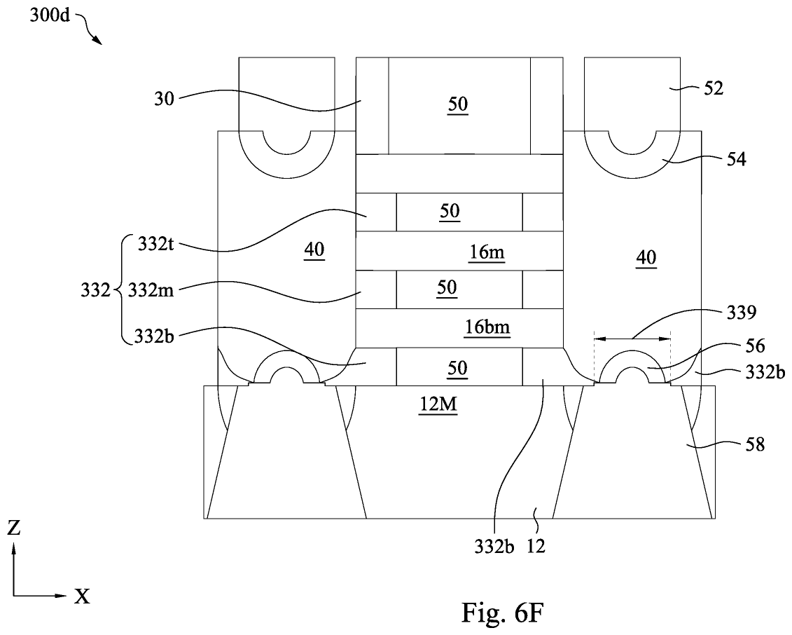

FIG. 6A schematically demonstrates a semiconductor device 300 according to embodiments of the present disclosure. The semiconductor device 300 includes inner spacers with extensions. The inner spacer extensions are formed on sidewalls of the bottommost inner spacers. In some embodiments, the inner spacer extensions are tapered in shape.

The semiconductor device 300 is a GAA device with various features similar to the semiconductor device 10 described above. Particularly, the semiconductor device 300 includes semiconductor channels 16 formed between epitaxial source/drain regions 40. Gate structures 50 are formed over and surrounding the semiconductor channels 16. The semiconductor device 300 is formed by patterning a semiconductor stack 18 on a substrate 12 into semiconductor fins 20, forming sacrificial gate structures over the semiconductor fins 20, recessing the semiconductor fins 20 outside the sacrificial gate structures to form the epitaxial source/drain regions 40, and replacing the sacrificial gate structures with the gate structures 50.

The epitaxial source/drain region 40 are formed in physical contact with the semiconductor channel layers 16. In some embodiments, the number of semiconductor channel layers 16 is between 1 and 6. The semiconductor channel layer 16 positioned closest to a top surface 12f of the substrate 12 is referred to as a bottommost channel layer 16bm. The semiconductor channel layer 16 positioned farthest from the top surface 12f of the substrate 12 is referred to as a topmost channel layer 16tm. The semiconductor channel layers 16 positioned between the topmost channel layer 16tm and the bottommost channel layer 16bm are referred to as middle channel layers 16m. The semiconductor channels 16 are separated by a set of inner spacers 332 and are surrounded by the replacement gate 50. The replacement gate 50 may be a gate stack including an interfacial layer, a gate dielectric layer, and agate electrode layer. The gate electrode layer may further include one or more work function layers and one or more metal fill layers. Sidewall spacers 30 are disposed between the epitaxial source/drain regions 40 and the gate structure 50.

The semiconductor device 300 includes a bottom epitaxial layer 36 disposed below the epitaxial source/drain regions 40. The bottom epitaxial layer 36 may be an epitaxial semiconductor layer formed in the recess in the semiconductor substrate 12 between the mesa region 12M. The bottom epitaxial layer 36 is formed in the space of the semiconductor fins 20. The bottom epitaxial layer 36 is in contact with a shallow trench isolation layer 22 and/or the sidewall spacers 30. In some embodiments, the bottom epitaxial layer 36 is an epitaxial semiconductor material formed from the semiconductor substrate 12. The bottom epitaxial layer 36 may be a transitional layer between the crystalline structures of the semiconductor substrate 12 and the epitaxial source/drain region 40. In some embodiments, the bottom epitaxial layer 36 may be used as an alignment feature for forming backside source/drain contacts.

In some embodiments, the set of inner spacers 332 have different shapes and dimensions. As shown in FIG. 6A, the set of inner spacers 332 may include a top inner spacer 332t, which is disposed between the topmost channel layer 16tm and the neighboring middle channel layer 16m, and a bottom inner spacer 332b, which is disposed between the bottommost channel layer 16bm and the mesa portion 12m of the substrate 12. In some embodiments, the set of inner spacers 332 may further include one or more middle inner spacers 332m, which are positioned between the top inner spacers 332t and the bottom inner spacers 332b.

The bottom inner spacer 332b may be wider along the x-direction than the top inner spacer 332t and the middle inner spacers 332m. The bottom inner spacer 332b may extend towards the source/drain regions 40 to provide additional isolation between the source/drain region 40 and a mesa portion 12M of the substate 12.

In some embodiments, the bottom inner spacer 332 may include a main portion 332₀ and an extended portion 332₁. The main portion 332₀ is substantially similar to the top inner spacer 332t and the middle inner spacers 332m. The main portion 332₀ may be positioned within the channel region, i.e., does not extend beyond sidewalls 16s of the semiconductor channel layers 16. The extended portion 332₁ is disposed beyond the sidewalls 16s of the semiconductor channel layers 16 and into the source/drain region 40. In some embodiments, the extended portion 332₁ may be tapered in shape. For example, the extended portion 332₁ is thicker at a proximal end, which is in contact with the main portion 332₀ and thinner at a distal end which is away from the main portion 332₀.

In some embodiments, the main portion 332₀ and the extended portion 332₁ may be formed from separate processes. For example, the main portion 332₀ is formed prior to forming the bottom epitaxial layer 36 and the extended portion 332₁ is formed after forming the bottom epitaxial layer 36. In some embodiments, the main portion 332₀ and the extended portion 332₁ are formed from the same material. In other embodiments, the main portion 332₀ and the extended portion 332₁ include different materials.

The extended portion 332₁ of the bottom inner spacer 332b is disposed between the epitaxial source/drain region 40 and the bottom epitaxial layer 36, as a result, the bottom inner spacers 332b provide isolation between the epitaxial source/drain regions 40 and the mesa region 12M of the semiconductor substrate 12. As shown in FIG. 6A, the bottom profile 40b of the source/drain region 40 may include two side sections 40bs and a central section 40bc. The bottom section 40bs are in contact with the bottom inner spacers 332b. The central section 40bc is in contact with the bottom epitaxial layer 36. In some embodiments, at least of a portion of the bottom section 40bs is curved.

In some embodiment, a gap remains between the bottom inner spacers 332b from opposing sides of a source/drain region 40 so that the source/drain region 40 is in direct contact with the corresponding bottom epitaxial layer 36. In some embodiments, during fabrication, a portion of the bottom semiconductor layer 36 functions as a seed layer to grow the epitaxial source/drain region 40, which may increase the volume of the source/drain region 40. The increased volume of the epitaxial source/drain region 40 adds compressive force F to the semiconductor channel layers 16. The increased compressive force F causing compressive strain in the semiconductor channel layers 16 thereby increasing mobility of the channel region.

The semiconductor device 300 may further include source/drain contacts 52 disposed on the epitaxial source/drain regions 40. A silicide layer 54 may be formed between the source/drain contacts 52 and the epitaxial source/drain regions 40 to facilitate electrical connection therebetween. A contact etch stop layer (CESL) 42 is deposited over the epitaxial source/drain regions 40 to protect the epitaxial source/drain regions 40 during formation. An interlayer dielectric (ILD) 44 is deposited over the CESL 42 to provide electrical isolation to the S/D contacts 52 and the epitaxial source/drain regions 40.

The extended portion 332₁ of the bottom inner spacers 332b prevents the epitaxial source/drain regions 40 from contacting with the mesa region 12M, therefore, eliminating an unwanted leakage current could flow between the epitaxial source/drain region 40 via the mesa portion 12M. The extended portion 332₁ of the bottom inner spacers 332b in the semiconductor device 300 offers adequate electrical isolation to the epitaxial source/drain regions 40 and leakage current suppression.

FIG. 6B is an enlarged view of the semiconductor device 300 in the rectangular area 6B in FIG. 6A showing details of the bottom inner spacer 332b. The top inner spacer 332t and the middle inner spacer 332m have substantially rectangle shaped cross sections in the x-z plane. The top inner spacer 332t has a width W3321 along the x direction and a height H₃₃ at along the z-direction. The middle inner spacer 332m has a width W₃₃₂ₘ along the x direction and a height H₃₃₂ₘ along the z-direction. Depending on the device design, the width W₃₃₂ₜ and the width W₃₃₂ₘ may be different or substantially similar. In some embodiments, the width W₃₃₂ₜ and the width W₃₃₂ₘ are in a range between about 1 nm and about 8 nm. Depending on the device design, the height H₃₃₂ₜ and the height H₃₃₂ₘ may be different or substantially similar. In some embodiments, the height H₃₃₂ₜ and the height H₃₃₂ₘ are in a range between about 1 nm and about 12 nm.

The cross section of the bottom inner spacer 332b in the x-z plane may be of irregular shape. The bottom inner spacer 332b has a top surface 332bt in contact with the bottommost channel layer 16bm, a bottom surface 332bb in contact with the mesa portion 12M and the bottom epitaxial layer 36, a gate-facing sidewall 332bg in contact with the gate structure 50, and a S/D-facing sidewall 332ss in contact with source/drain region 40. In some embodiments, the S/D-facing sidewall 332ss may include a curved portion.

The bottom inner spacer 332b has a varying width. As shown in FIG. 6B, the bottom inner spacer 332b has a top width W332bt at the top surface 332bt, where the bottom inner spacer 332b is in contact with the bottommost channel layer 16bm, and a bottom width W_{332bb} at a bottom surface 332bb, wherein the bottom inner spacer 332b is in contact with the substrate 12 and the bottom epitaxial layer 36. In some embodiments, the bottom width W_{332bb} is greater than the top width W_{332bt}. In some embodiments, the bottom surface 332bb of the bottom inner spacer 332b has the largest width among the set of inner spacers 332. The bottom width W_{332bb} may be similar to the width W₃₃₂ₜ and the width W₃₃₂ₘ. In some embodiments, the width W_{332bt} is in a range between about 1 nm and about 8 nm. In some embodiments, the width W_{332bb} is in a range between about 1 nm and about 15 nm. In some embodiments, a ratio of the width W_{332bb} over the width W_{332bt} is in a range between about 1.1 and about 3.0.

The bottom inner spacer 332b has a varying height. As shown in FIG. 6B, the main portion 332₀ of the bottom inner spacer 332b, which is in contact with the bottommost channel layer 16bm, has a main height H_{332b}. The extend portion 332₁ of the bottom inner spacer 332b has a height which gradually reduces from a proximal height H₃₃₂ₚ to a distal height H_{332d}. In some embodiments, the main height H_{332b} is in a range between about 1 nm and about 12 nm. The proximal height H₃₃₂ₚ is in a range between about 1 nm and about 12 nm. In the embodiment of FIG. 6B, the proximal height H₃₃₂ₚ is substantially similar to the main height H_{332b}. The distal height H_{332d} is in a range between about 0 nm and about 10 nm. In some embodiments, a ratio of the distal height H_{332d} over the proximal height H₃₃₂ₚ is in a range between about 0 and about 0.85.

In some embodiments, the S/D-facing sidewall 332ss may include a curved section 332sc and a bottom section 332sb. The curved section 332sc reflects the height decrease from the proximal end to the distal end. In some embodiments, the curved section 332sc forms a top angle with an x-y plane at the proximal end and a bottom angle θ_{B} with an x-y plane at the distal end. In some embodiments, the top angle θ_{T} is in a range between about 5° and about 90°. In some embodiments, the bottom angle θ_{B} is in a range between about 5° and about 90°.

In some embodiments, the inner spacers 332 are formed from one or more suitable dielectric material of various dielectric constant values. In some embodiments, the inner spacers 332 may be formed from silicon oxide, silicon nitride, silicon oxynitride with carbon, silicon carbon nitride (SiCN), silicon carbon oxy-nitride (SiCON), other suitable dielectric material, and a combination thereof. In some embodiments, the main portion 332₀ and the extended portion 332₁ of the bottom inner spacer 332b may be formed from the same dielectric material. In other embodiments, the main portion 332₀ and the extended portion 332₁ are formed from different dielectric material.

It should be noted that characteristics of various material components in the semiconductor device 300 may be similar to the components with the same reference numerals in the semiconductor device 10 and 200 described above.

FIG. 6C is an enlarged view of a semiconductor device 300a according to embodiments of the present disclosure. The semiconductor device 300a is similar to the semiconductor device 300 except that the bottom inner spacer 332b in the semiconductor device 300a includes an extended portion 332₁ with a proximal height H₃₃₂ₚ shorter than the main height H_{332b} of the main portion 332₀. As a result, the S/D-facing sidewall 332ss of the bottom inner spacer 332b includes a top section 332st, a curved section 332sc, and a bottom section 332sb. The top section 332st may be substantially vertical. In some embodiments, the top section 332st has a height H₃₃₂ₛₜ. The height H₃₃₂ₛₜ is in a range between about 0 nm and about 8 nm. In some embodiments, a ratio of the distal height H₃₃₂ₛₜ over the main height H_{332b} is in a range between about 0 and about 0.67.

FIG. 6D is an enlarged view of a semiconductor device 300b according to embodiments of the present disclosure. The semiconductor device 300b is similar to the semiconductor device 300a except that the bottom inner spacer 332b in the semiconductor device 300b extends below the top surface 12f of the substrate 12. The bottom surface 332bb of the bottom inner spacer 332b is non-planar. Particularly, the bottom surface 332bb include a main portion 332p0, which is planar and in contact with the mesa portion 12M, and an extended portion 332p1, which is sloped downwards and in contact with the bottom epitaxial layer 36. In some embodiments, the extended portion 332p1 may be curved. The extended portion 332₁ of the bottom inner spacer 332 extends downwards. In some embodiments, the bottom inner spacer 332b extends below the top surface 12f of the substrate 12 for a height H_{332eb}. In some embodiments, the height H_{332eb} is in a range between about 0 nm and about 8 nm. The bottom inner spacer 332 has a height H′332b. The height H′_{332b} of the bottom inner spacer 332b is greater than the height H₃₃₂ of the top inner spacers 332t and the middle inner spacers 332m. In some embodiments, the height H′332b is in a range between about 0 nm and about 20 nm.

FIG. 6E is an enlarged view of a semiconductor device 300c according to embodiments of the present disclosure. The semiconductor device 300c is similar to the semiconductor device 300b except that the bottom surface 332bb of the bottom inner spacer 332b is non-planar and disposed above the top surface 12f of the substrate 12. Particularly, the bottom surface 332bb include a main portion 332p0, which is planar and in contact with the mesa portion 12M, and an extended portion 332′ₚ₁, which is sloped upwards and in contact with the bottom epitaxial layer 36. In some embodiments, the extended portion 332′p1 may be curved. The extended portion 332₁ of the bottom inner spacer 332 is disposed above the top surface 12f of the substrate 12. In some embodiments, the bottom inner spacer 332b extends above the top surface 12f of the substrate 12 for a height H_{332′eb}. In some embodiments, the height H_{332′eb} is in a range between about 0 nm and about 8 nm. The bottom inner spacer 332 has a height H″_{332b}. The height H″_{332b} of the bottom inner spacer 332b is similar to the height H₃₃₂ of the top inner spacers 332t and the middle inner spacers 332m. In some embodiments, the height H″_{332b} is in a range between about 0 nm and about 12 nm.

FIG. 6F schematically demonstrate a semiconductor device 300d according to embodiments of the present disclosure. The semiconductor device 300d is similar to the semiconductor device 300, 300a, 300b, and 300c, except that the semiconductor device 300d includes backside source/drain contact features 58. In some embodiments, a silicide layer 56 is formed between the backside source/drain contact features 58 and the source/drain region 40.

As shown in FIG. 6F, the backside source/drain contact features 58 are in contact with the bottom surface 332b of the bottom inner spacer 332. Particularly, the backside source/drain contact features 58 may be in contact with the extended portion 332₁ of the bottom inner spacer 332. As shown in FIG. 6F, there is a gap 339 between the bottom inner spacers 332b on opposing sides of the source/drain region 40. The backside source/drain contact features 58 extends through the gap 339 to form contact with the source/drain region 40. During fabrication, the bottom inner spacer 332b may function as an etch stop layer while form openings for the backside source/drain contact features 58.

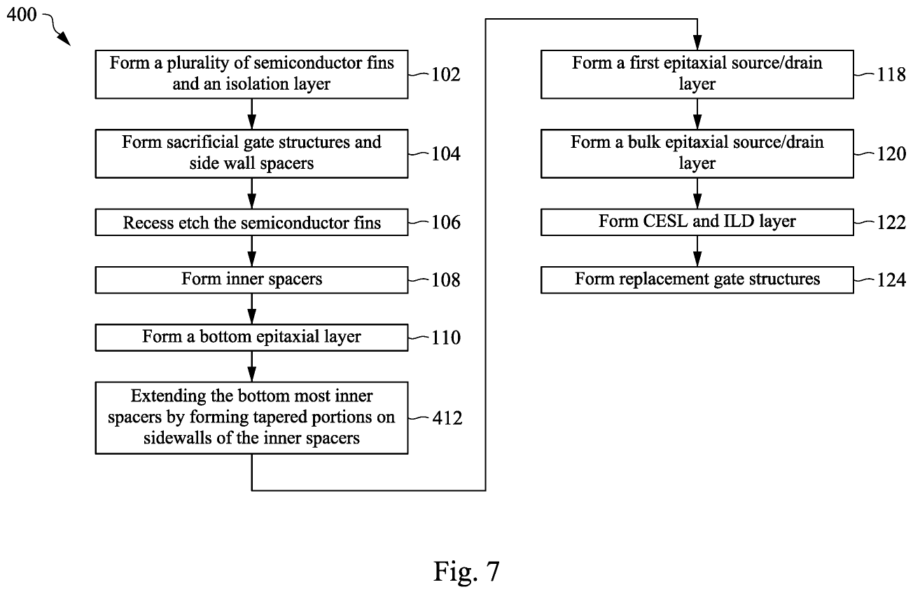

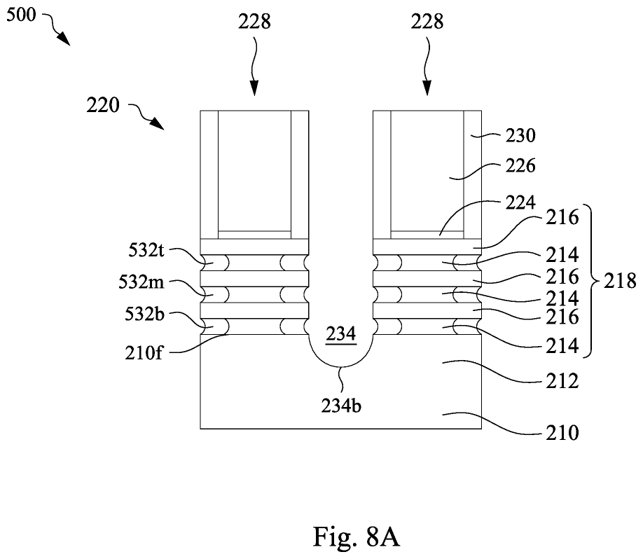

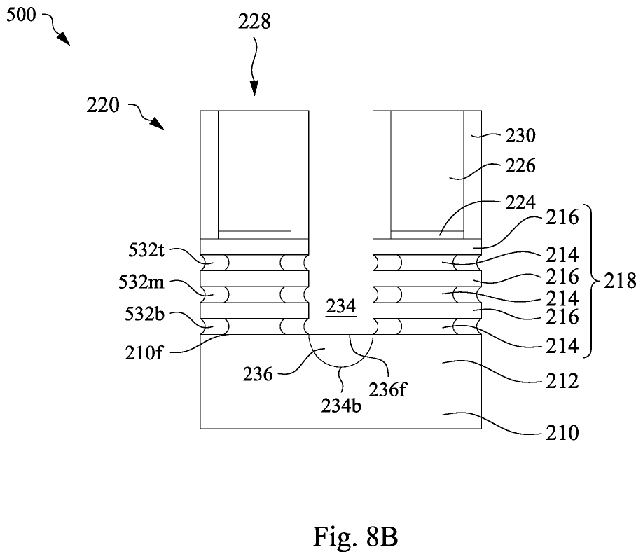

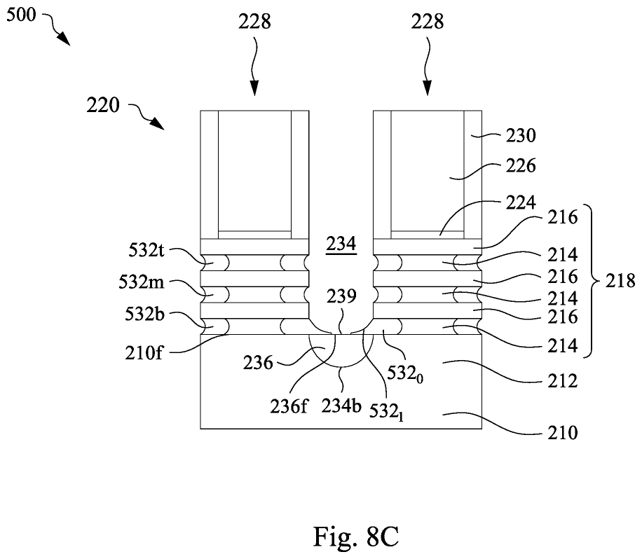

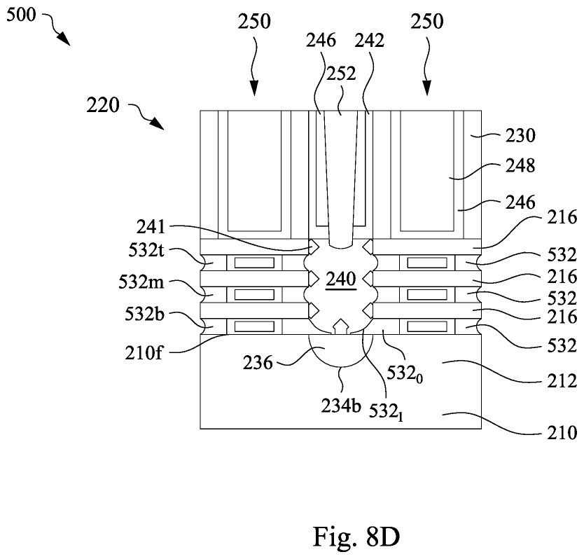

FIG. 7 is a flow chart of a method 400 for manufacturing of a semiconductor substrate according to embodiments of the present disclosure. FIGS. 8A-8D schematically illustrate various stages of manufacturing a semiconductor device 500 using the method 400. The method 400 may be used to fabricate the semiconductor devices 300, 300a, 300b, 300c, and 300d described above. The method 400 includes various operations described in the method 100.

FIG. 8A is a schematic cross sectional view of the semiconductor device 500 after operation 102, 104, 106, and 108, which are described above. The method 500 begins at operation 102 where a plurality of semiconductor fins 220 are formed over a substrate 210. In operation 104, sacrificial gate structures 228 and spacer layers 230 are then formed over the semiconductor fins 220. In operation 106, the semiconductor fins 220 on opposite sides of the sacrificial gate structure 228 are recess etched, forming source/drain recesses 234 between the neighboring sacrificial gate structures 228.

In operation 108, inner spacers 532 are formed on exposed ends of the first semiconductor layers 214 under the sacrificial gate structures 228, as shown in FIG. 8A. The first semiconductor layers 214 exposed to the source/drain recesses 234 are first etched horizontally along the X direction to form spacer cavities. In some embodiments, the first semiconductor layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In some embodiments, the amount of etching of the first semiconductor layer 214 is in a range between about 1 nm and about 8 nm along the X direction.

After forming the spacer cavities at opposite ends of the first semiconductor layers 214, the inner spacers 532 can be formed in the spacer cavities by conformally depositing an insulating layer. The insulation layer is then partially removed to form the inner spacer 532. The insulating layer can be formed by ALD or any other suitable method. The subsequent etch process removes most of the insulating layer except inside the cavities, resulting in the inner spacers 532. The inner spacers 532 includes two or more segments, alternately stacked with the second semiconductor layers 216.

The inner spacers 532 may be formed from a single layer or multiple layers of dielectric material. In some embodiments, the inner spacers 532 may include silicon oxide, silicon nitride, silicon oxynitride with carbon, silicon carbon nitride (SiCN), silicon carbon oxy-nitride (SiCON), other suitable dielectric material, and a combination thereof. The inner spacer 532 may have a thickness in a range from about 1 nm to about 8 nm along the X direction.

The inner spaces 532 may include a top inner spacer 532t, a bottom inner spacer 532b, and middle inner spacer 532m when number of channel layers 216 is greater than 2. As shown in FIG. 8A, cross sections of the top inner spacer 532t, the bottom inner spacer 532b, and the middle inner spacer 532m are substantially similar.

In operation 110, a bottom epitaxial layer 236 is formed in lower portions of the source/drain recesses 234, as shown in FIG. 8B. In some embodiments, the bottom epitaxial layer 236 fills the lower portions of the source/drain recesses 234 to a level below the top surface 210f of the substrate 212. In some embodiment, a front surface 236f may be planar, concave as in the semiconductor device 300b in FIG. 6D, or convex as in the semiconductor device 300c in FIG. 6E.

In operation 412, extended portions 5320 are formed on sidewalls of the bottom inner spacers 532b, as shown in FIG. 8C. The bottom dielectric layer 238 is formed on the front surface 236f of the bottom epitaxial layer 236. The shape and dimension of the extended portions 5320 may be similar to the extended portions 3230 in the semiconductor device 300, 300a, 300b, 300c, 300d. For example, cross-section of the extended portions 5230 may be tapered extending into the source/drain recesses 234.

The extended portions 5321 may be formed by a directional deposition process with bottom up to sidewall growth selectivity. For example, the extended portions 5321 may be formed by a directional PECVD process. For example, the extended portions 5321 may be formed in at a temperature between about 50° C. and about 600° C., for example between about 300° C. and about 500° C. The process may be performed at a pressure in a range between about 50 m torr and about 50 torr, for example between about 50 m torr and about 2 torr. Suitable precursors may include one or more SiH₄, H₂SiCl₂ (DCS), H₂Sil₂, NH₃, N₂, H₂, Ar, and He.

In some embodiments, the extended portions 5321 may be formed by depositing a conformal dielectric layer over the exposed surface and then selectively removing the conformal dielectric layer from vertical surfaces and outer surfaces, leaving a portion at corners of the bottom inner spacer 532b and the bottom epitaxial layer 236. In some embodiments, the bottom dielectric layer 238 may be formed from any suitable dielectric material, such as silicon oxide, silicon nitride, silicon oxynitride with carbon, silicon carbon nitride (SiCN), silicon carbon oxy-nitride (SiCON), other suitable dielectric material, and a combination thereof. In some embodiments, the extended portions 5321 may be formed from the same material as the inner spacers 532t, 532m, 532b formed in operation 108. In other embodiments, the extended portions 5321 may be formed from the different material as the inner spacers 532t, 532m, 532b formed in operation 108.

As shown in FIG. 8C, a gap 239 remains between two bottom inner spacers 232b exposing the top surface 236f of the bottom epitaxial layer 236. The exposed portion of the bottom epitaxial layer 236 can be used as a seed layer during epitaxial growth of the source/drain region.

In operation 118, a first epitaxial source/drain layer 241 is formed in the source/drain recess 234, as shown FIG. 8D. The first epitaxial source/drain layer 241 is formed by an epitaxial growth method using CVD, ALD or molecular beam epitaxy (MBE). The first epitaxial layer 241 is grow from exposed semiconductor surfaces, i.e., the sidewall 216s of the semiconductor layer 216 and the top surface 236t of the bottom epitaxial layer 236.

In operation 120, a bulk epitaxial source/drain layer 243 is formed over the first epitaxial source/drain layer 241, as shown in FIG. 8D. The bulk epitaxial source/drain layer 243 fills the source/drain recess 234. The first epitaxial source/drain layer 241 and the bulk epitaxial source/drain layer 243 form epitaxial source/drain regions 240. The extended portions 5321 extend between the source/drain regions 240 and the bottom epitaxial layer 236.

In operation 122, a contact etch stop layer (CESL) 242 and an interlayer dielectric (ILD) layer 244 are formed over the exposed surfaces as shown in FIG. 8D. In operation 124, replacement gate structures 250 are formed in place of the sacrificial gate structures 228. The replacement gate structures 250 are then formed around the channel region. A gate dielectric layer 246 is formed around each of the second semiconductor layers 216 and a gate electrode layer 248 is formed on the gate dielectric layer 246. The gate dielectric layer 246 and the gate electrode layer 248 may be referred to as a replacement gate structure 250.

After the formation of the gate electrode layer 248, a planarization process, such as a CMP process, is performed to remove excess deposition of the gate electrode material and expose the top surface of the ILD layer 244. In some embodiments, source/drain contacts 252 are formed in the ILD layer 244. Prior to forming the front side source/drain contacts 252, contact holes are formed in the ILD layer 244, the CESL 242, and a portion of the epitaxial source/drain regions 240.

Various embodiments or examples described herein offer multiple advantages over the state-of-art technology. The semiconductor device according to the present disclosure has reduced channel resistance (R_{ch}), with improved AC performance, and minimized DC performance loss from R_{ch} degradation.

It will be understood that not all advantages have been necessarily discussed herein, no particular advantage is required for all embodiments or examples, and other embodiments or examples may offer different advantages.

Some embodiments of the present provide a semiconductor device. The semiconductor device comprises two or more semiconductor channel layers stacked over a top surface of a semiconductor substrate; a bottom inner spacer disposed between a bottommost semiconductor channel layer and the top surface of the semiconductor substrate; an epitaxial source/drain region connected to the two or more semiconductor channel layers, wherein the epitaxial source/drain region includes a sidewall facing the two or more semiconductor channel layers and a bottom surface connected to the sidewall; and a bottom epitaxial layer in contact with the bottom surface of the epitaxial source/drain region, wherein the bottom inner spacer extends between the bottom epitaxial layer and the epitaxial source/drain region.

Some embodiments of the present provide a semiconductor device. The semiconductor device comprises a semiconductor substrate; two or more semiconductor channel layers vertically stacked above a top surface of the semiconductor substrate; an epitaxial source/drain region grown from the two or more semiconductor channel layers; two or more inner spacers disposed alternately stacked with the two or more semiconductor channel layers, wherein the two or more inner spacers include a bottom inner spacer, wherein the bottom inner spacer comprises: a main portion disposed between a bottommost semiconductor channel layer and the top surface of the semiconductor substrate; and an extended portion extending from a sidewall of the main portion, wherein the extended portion extends beyond the two or more semiconductor channel layers and under a bottom surface of the epitaxial source/drain region.

Some embodiments provide a method for forming a semiconductor device. The method comprises forming a semiconductor fin on a top surface of a semiconductor substrate, wherein the semiconductor fin comprises first semiconductor layers and second semiconductor layers alternately arranged; forming a source/drain recess through the semiconductor fin and into the semiconductor substrate; recessing the first semiconductor layers to form inner spacer cavities; forming inner spacers in the inner spacer cavities, wherein the inner spacers include a bottom inner spacer disposed between the top surface of the semiconductor substrate and a bottommost second semiconductor layer; extending bottom inner spacer towards the source/drain recess; and growing an epitaxial source/drain region from the second semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
two or more semiconductor channel layers stacked over a top surface of a semiconductor substrate;
a bottom inner spacer disposed between a bottommost semiconductor channel layer and the top surface of the semiconductor substrate;
an epitaxial source/drain region connected to the two or more semiconductor channel layers, wherein the epitaxial source/drain region includes a sidewall facing the two or more semiconductor channel layers and a bottom surface connected to the sidewall; and
a bottom epitaxial layer in contact with the bottom surface of the epitaxial source/drain region, wherein the bottom inner spacer extends between the bottom epitaxial layer and the epitaxial source/drain region.

2. The semiconductor device of claim 1, wherein the bottom inner spacer includes:
a top surface in contact with the bottommost semiconductor channel layer; and
a bottom surface in contact with the top surface of the semiconductor substrate and the bottom epitaxial layer.

3. The semiconductor device of claim 2, wherein the bottom inner spacer has a first width at the top surface and a second width at the bottom surface, and the second width is greater than the first width.

4. The semiconductor device of claim 3, wherein the bottom inner spacer further includes:
a first sidewall connecting between the top surface and the bottom surface, wherein the first sidewall is in contact with the epitaxial source/drain region, wherein the first sidewall includes a curved portion.

5. The semiconductor device of claim 2, wherein the bottom surface is a planar surface.

6. The semiconductor device of claim 2, wherein the bottom surface includes a planar portion and a sloped portion.

7. The semiconductor device of claim 6, wherein the sloped portion extends below the top surface of the semiconductor substrate.

8. The semiconductor device of claim 6, wherein the sloped portion extends above the top surface of the semiconductor substrate.

9. The semiconductor device of claim 1, wherein the bottom inner spacer comprises:
a main portion disposed between the bottommost semiconductor channel layer and the top surface of the semiconductor substrate; and
an extended portion extending from a sidewall of the main portion, wherein the extended portion is disposed between the epitaxial source/drain region and the bottom epitaxial layer.

10. The semiconductor device of claim 9, wherein the extended portion has a proximal end in contact with the main portion and a distal end away from the main portion, and the extended portion tapers from the proximal end to the distal end.

11. A semiconductor device, comprising:
a semiconductor substrate;
two or more semiconductor channel layers vertically stacked above a top surface of the semiconductor substrate;
an epitaxial source/drain region grown from the two or more semiconductor channel layers;
two or more inner spacers disposed alternately stacked with the two or more semiconductor channel layers, wherein the two or more inner spacers include a bottom inner spacer, wherein the bottom inner spacer comprises:
a main portion disposed between a bottommost semiconductor channel layer and the top surface of the semiconductor substrate; and
an extended portion extending from a sidewall of the main portion, wherein the extended portion extends beyond the two or more semiconductor channel layers and under a bottom surface of the epitaxial source/drain region.

12. The semiconductor device of claim 11, wherein the extended portion includes:
a proximal end in contact with the sidewall of the main portion; and
a distal end away from the main portion, and the extended portion tapers from the proximal end to the distal end.

13. The semiconductor device of claim 11, wherein the main portion and the extended portion are formed from the same material.

14. The semiconductor device of claim 11, wherein the main portion and the extended portion are formed from different materials.

15. The semiconductor device of claim 11, further comprises a bottom epitaxial layer in contact with the epitaxial source/drain region, wherein the extended portion of the bottom inner spacer is disposed between the bottom epitaxial layer and the epitaxial source/drain region.

16. A method comprising:
forming a semiconductor fin on a top surface of a semiconductor substrate, wherein the semiconductor fin comprises first semiconductor layers and second semiconductor layers alternately arranged;
forming a source/drain recess through the semiconductor fin and into the semiconductor substrate;
recessing the first semiconductor layers to form inner spacer cavities;
forming inner spacers in the inner spacer cavities, wherein the inner spacers include a bottom inner spacer disposed between the top surface of the semiconductor substrate and a bottommost second semiconductor layer;
extending bottom inner spacer towards the source/drain recess; and
growing an epitaxial source/drain region from the second semiconductor layers.

17. The method of claim 16, further comprising:
prior to extending the bottom inner spacer, growing a bottom epitaxial layer in the recess, wherein an extended portion of the bottom inner spacer is formed over the bottom epitaxial layer.

18. The method of claim 17, wherein a portion of the bottom epitaxial layer is exposed to the source/drain recess, and a portion of the epitaxial source/drain region is grown from the bottom epitaxial layer.

19. The method of claim 16, wherein extending the bottom inner spacer comprises:
forming a tapered portion on a sidewall of the bottom inner spacer.

20. The method of claim 16, further comprising:
forming a backside source/drain contact feature, wherein the backside source/drain contact feature is in contact with the extended portion of the bottom inner spacer.
